(19) United States
(12) Patent Application Publication
(10) Pub. No.: US 2020/0185885 A1
(43) Pub. Date: Jun. 11, 2020

(54) UNIPOLAR LIGHT DEVICES INTEGRATED WITH FOREIGN SUBSTRATES AND METHODS OF FABRICATION

(71) Applicant: The Regents of the University of California, Oakland, CA (US)

(72) Inventors: Alan Young Liu, New Orleans, LA (US); Alexander Spott, Seattle, WA (US); Arthur Gossard, Santa Barbara, CA (US); John Bowers, Santa Barbara, CA (US)

(21) Appl. No.: 16/614,722

(22) PCT Filed: May 18, 2018
(86) PCT No.: PCT/US2018/033439

§ 371 Date: Nov. 18, 2019

Related U.S. Application Data
(60) Provisional application No. 62/509,082, filed on May 20, 2017.
(60) Provisional application No. 62/508,812, filed on May 19, 2017.

(51) Int. Cl. H01S 5/34; H01S 5/02; H01S 5/10; H01S 5/12; H01S 5/347; H01S 5/343

(52) U.S. Cl. CPC H01S 5/3402; H01S 5/021; H01S 5/1032; H01S 5/34326; H01S 5/1237; H01S 5/3427; H01S 5/347; H01S 5/0215

(57) ABSTRACT

A light emitting device includes a unipolar light emitter structured from materials arranged to provide light emission via intersubband transitions of a single type of carrier in either of the conduction band or valence band integrated with a foreign surface.

### PRIORITY CLAIM AND REFERENCE TO RELATED APPLICATION

This application is a 35 U.S.C. § 371 National Phase Application and claims priority under 35 U.S.C. § 365, 35 U.S.C. § 119 and all applicable statutes and treaties from prior PCT Application PCT/US2018/033439 filed May 28, 2018, which claims priority from U.S. provisional application Ser. No. 62/508,812, which was filed May 19, 2017, and from U.S. provisional application Ser. No. 62/509,082, which was filed May 20, 2017.

### STATEMENT OF GOVERNMENT INTEREST

This invention was made with government support under no. FA8650-15-2-5220 from Air Force Research Laboratory. The government has certain rights in the invention.

### FIELD

A field of the invention is semiconductor light emitting devices, and particularly unipolar light emitting devices. An example device of the invention is a quantum cascade laser.

### BACKGROUND

Silicon provides advantages compared to native III-V substrates. Advantages include low cost, high thermal conductivity, and mechanical durability. However, silicon's indirect bandgap requires integration with Group III-V active devices to achieve efficient light emitting devices. A problem encountered with such integrations is carrier trapping at defects of the interface.

Unipolar light emitting devices are devices in which photons are generated due to intersubband transitions by the same type of carrier from a higher state to a lower state on the same side of the bandgap, versus conventional light emitting devices (such as diode lasers) which rely on the bipolar recombination of electrons in the conduction band with holes in the valence band. These states are usually electronic states arising from quantum confinement, meaning that the energy levels and the optical transition energy is directly tunable over a wide range by controlling the size of the quantum confined nano structure as well as the composition of the surrounding material. The most prominent example of a unipolar light emitting device is that of the quantum cascade laser, which has important commercial applications in chemical sensing and spectroscopy, and which allows for the creation of lasers with wavelengths outside the realm of possibility afforded by conventional semiconductor lasers using interband bipolar recombination. Another example unipolar light emitting device provided in Gauthier-Lafaye, et al., “Long-wavelenth (≈15.5 μm) Unipolar Semiconductor Laser in GaAs Quantum Wells,” Appl. Phys. Lett 71 (25) pp. 3619-21 (1997).

Quantum cascade lasers typically have emission wavelengths that range from the mid-infrared (˜2 μm) to terahertz wavelengths (>100 μm). These wavelengths are typically outside the realm of possibility of traditional GaAs or InP p-i-n junction based lasers using electron-hole recombination processes for photon generation, which are constrained by the available bandgaps of III-V semiconductors to wavelengths shorter than ˜2.6 μm. Interband cascade lasers (ICLs), which also utilize electron-hole recombination processes for photon generation are limited to emission wavelengths of ˜2.9 μm to ˜7 μm. The longer wavelengths available with QCLs match the absorption lines of many complex molecules as well as atmospheric transmission windows, lending them to a variety of applications such as remote gas sensing in industrial exhaust systems, breath analysis in medical diagnostics, and heat-seeking missile countermeasures for the military, to name a few. These lasers are typically manufactured on lattice matched III-V compound semiconductor substrates such as InP or GaAs (and GaSb or InAs to a lesser extent). The aforementioned III-V substrates are expensive, manufactured from rare materials, toxic to humans and brittle in nature.

Diode lasers have been fabricated on silicon by heterogeneous integration, where the active III-V layers are transferred from the native III-V substrate to the silicon substrate by wafer- or die-bonding. The fabrication of diode lasers on silicon with this technique has been investigated in the art, including by some of the present inventors. A review of photonic integrated circuits constructed with heterogeneously integrated devices on silicon, where the III-V material is bonded to the silicon platform, is provided in T. Komljenovic, et al. “Heterogeneous Silicon Photonic Integrated Circuits,” J. Lightwave Technol. 34, 20-35 (2015). Another publication concerns heterogeneous optical amplifiers. M. L. Davenport, et al, “Heterogeneous Silicon/III-V Semiconductor Optical Amplifiers,” IEEE J. Select. Topics Quantum Electron., vol. 22, no. 6, p. 3100111, (November 2016).

Diode lasers have also been fabricated on silicon by epitaxially growing the III-V layers directly onto a silicon substrate, rather than the native lattice-matched III-V substrate. Much of the focus is upon limiting the defects that act as carrier traps. Liu et al., “Quantum dot lasers for silicon photonics,” Photon. Res., Vol. 3, No. 5 (October 2015), reports on substituting quantum dot active regions in place of quantum wells to mitigate the negative effect of residual dislocations on laser performance. Liu et al., “Reliability of InAs/GaAs Quantum Dot QD lasers grown on GaAs Lasers Epitaxially Grown on Silicon,” IEEE Journal of Selected Topics in Quantum Electronics, Vol. 21, No. 6 (November/December 2015) reported on QD lasers that exhibited good lifetime characteristics, and determined that the degradation of QD lasers on silicon is caused by either the higher dislocation density from growth on silicon and/or damage induced from the facet polishing process. Wan et al. reported on a laser structure with quantum dots localized in v-grooves a silicon substrate to provide high-crystalline-quality GaAs and self-organized InAs/GaAs quantum dots on-V-grooved-Si substrates. Wan et al., “InAs/GaAs quantum dots on GaAs-on-V-grooved-Si substrate with high optical quality in the 1.3 μm band,” Appl. Phys. Lett. 107, 081106 (2015). Wang et al. report a distributed feedback InP laser grown on silicon with defects isolated via a selective area growth process that suppresses threading dislocations and anti-phase boundaries to a less than 20-nm-thick layer to improve device performance. Wang et al., “Room-temperature InP distributed feedback laser array directly grown on silicon,” Nature Photonics, Vol. 9, (December 2015). Such reports are typical of efforts to improve performance of diode lasers on silicon, with efforts focused on reducing the number of defects at the silicon/active device layer interface.

Recently, Jung et al. reported on quantum cascade laser sources bonded to silicon substrates via an SU-8 adhesive. Jung et al., “Terahertz difference-frequency quantum cascade laser sources on silicon,” Optica, Doc. ID 278379 (Dec. 22, 2016). The fabrication process involves growth of the active device layers and the lithographic definition of laser mesas and metallization on a native Group III-V substrate. A multi-step transfer-printing process is then applied to adhesive-bond the fully-fabricated laser to a silicon substrate. Unlike heterogeneous integration provided in the present invention, in a transfer-printing process the laser geometries are defined on the native substrate prior to transferring the active material to the foreign substrate. The laser mesas therefore cannot be lithographically aligned to features, such as waveguides that are on the foreign substrate. Also compared to some preferred embodiments of heterogeneous integration provided in the present invention, Jung et al. does not report thermal advantages, and requires the SU-8 adhesive to bond the III-V layers to the silicon substrate.

### SUMMARY OF THE INVENTION

A preferred embodiment is light emitting device. A unipolar light emitter structured from materials arranged to provide light emission via intersubband transitions of a single type of carrier in either of the conduction band or valence band is integrated with a foreign substrate.

Preferred materials include Group III-V device layers of (InₓAl_{y}Ga_{z})_{0.5}(AsᵤPᵥN_{w})_{0.5}, where x+y+z=1, u+v+w=1. Additional preferred Group III-V device layers contain Sb, of (InₓAl_{y}Ga_{z})_{0.5}(SbₜAsᵤPᵥN_{w})_{0.5}, where x+y+z=1, t+u+v+w=1.

Preferred materials of the unipolar emitter are Group II-VI device layers including Zn, Cd, or Hg with O, S, Se, or Te. Additional preferred materials of the unipolar emitter are Group IV device layers including Ge, Si, or Sn.

Preferred devices include a quantum cascade laser, and devices that include quantum dots or quantum dashes, rather than quantum wells, for light emission, and also the unipolar light emitter comprises a quantum dot cascade laser.

Preferred devices emit light of a wavelength in the mid-infrared wavelength range 2-20 μm, or 1-2 μm, or in a wavelength in the Terahertz regime, 20 μm to 1 mm Additional preferred devices emit at near 1.55 μm or 1.3 μm.

The active layers of the unipolar light emitter can be wafer bonded to the foreign surface, or can be epitaxially grown on the foreign surface. There can be a cladding layer on the foreign surface. The materials can be selected and arranged such that radiative relaxations dominate over non-radiative relaxations.

The foreign surface can be, for example, silicon, germanium, glass, sapphire, diamond, an oxide layer or a buffer layer. The foreign surface in one example is silicon and the device includes a quantum cascade laser heterogeneously integrated on the silicon with a silicon-on-nitride-on-insulator (SONOI) ultra-broadband waveguide platform.

Devices can include a waveguide integrated with the unipolar light emitter and foreign substrate. The foreign surface can be a waveguide on a substrate. The device can include a buffer layer, bottom metal, active stages, cladding above and below the active stages, and a top metal. Cladding above and below can consists of InP, and the cladding around can consists of SiN. There can be cladding layers above or below the waveguide.

A substrate can be silicon and the waveguide germanium. The substrate can be silicon and the waveguide can be silicon with buried oxide separating the silicon waveguide from the silicon substrate. Silicon nitride can separate the silicon waveguide from the silicon substrate. The substrate can be silicon and the waveguide can be silicon with silicon nitride separating the silicon waveguide from the silicon substrate. The substrate can be silicon and the waveguide can be silicon nitride with silicon dioxide separating the silicon nitride waveguide from the silicon substrate.

Devices of the invention can be part of a photonic integrated circuit. Devices can be integrated with passive waveguide regions of III-V materials. Devices can be integrated with passive waveguide regions of the same material as the unipolar light emitter. Devices can be integrated with passive waveguide regions previously integrated on the foreign substrate. Devices can be integrated with passive waveguide regions of materials which are neither previously integrated with the foreign substrate, or made of III-V materials. Devices can be integrated with passive waveguide regions formed by materials integrated after the unipolar light emitter is integrated with the foreign surface.

Devices can be integrated with passive waveguide regions of chalcogenide glasses. Devices can be integrated with passive or active waveguides or devices including materials integrated after the unipolar light emitting device is integrated with the foreign surface.

### BRIEF DESCRIPTION OF THE DRAWINGS

FIGS. 1A-1D are band diagrams that illustrate radiative and nonradiative transitions that can occur for conventional electron-hole recombination light emitters (1A and 1B) and unipolar light emitters (1C and 1D) with or without the presence of defects within the forbidden band gap in a III-V semiconductor laser;

FIG. 2 shows a simplified schematic of the conduction band structure for a quantum cascade laser;

FIGS. 3A-4B illustrate preferred embodiment quantum cascade lasers on foreign substrates, shown in cross-section;

FIGS. 5A-5D illustrate a preferred embodiment fabrication process;

FIGS. 6A-6C illustrate the resulting structure from variations of the fabrication process of FIGS. 5A-5D;

FIGS. 7A to 7C illustrate (in optical microscope, polished end facet, and cross-sectional schematic active region view, respectively) a preferred embodiment quantum cascade laser heterogeneously integrated on silicon with a silicon-on-nitride-on-insulator (SONOI) ultra-broadband waveguide platform;

FIGS. 8A-8G shows a preferred fabrication process for a SONOI chip, as used in FIGS. 7A-7C;

FIGS. 9A-9J illustrate preferred steps to fabricate heterogeneously integrated QCLs by bonding QCL layers rather than epitaxially growing QCL layers, as used in FIGS. 7A-7C.

FIG. 9K shows single-sided optical output power and voltage vs. drive current of two integrated QCLs;

FIG. 10A shows Single-sided output power vs. drive current for experimental Device A at temperatures from 10° C. to 60° C.; FIG. 10B shows corresponding threshold current densities vs. temperature;

FIG. 11 shows the spectral emission from experimental Device B at 20° C.;

FIGS. 12A and 12B show far field intensity of experimental Device A as a function of the angle normal to the facet in the slow (horizontal) axis (top) and fast (vertical) axis (bottom);

FIG. 13 shows single-sided output power vs. drive current at 20° C. for experimental Device A before and after depositing an AR coating on the SONOI waveguide facets;

FIG. 14 shows pulsed light emission vs. current density from a 2-mm long DFB QCL with a 4-μm wide narrow mesa region and 1.5-μm wide Si waveguide, showing a threshold current of 80 mA.

FIG. 15A shows two preferred options for placing a Ge waveguide above a Si layer or substrate; FIG. 15B includes cross-sectional schematic and optical mode simulation of a QCL bonded to a Ge-on-Si waveguide.

FIG. 16 shows a multi-spectral laser architecture with multiple gain materials bonded onto a Si substrate, including QCL lasers and diode lasers;

FIG. 17A shows a micrograph of an AWG fabricated on SOI and designed to have a center wavelength of ˜3.61 μm and channel spacing of ˜10 nm; FIG. 17B shows a calculated low loss expected to be in the range 0.2-1.0 dB, and a crosstalk of −45 dB per channel;

FIG. 18A shows a three-dimensional (3D) illustration of a SONOI waveguide with an etched DFB surface grating underlying III-V layers; FIG. 18B illustrates the DFB QCL; FIG. 18C shows an integrated DFB QCL with one taper removed to expose a polished hybrid Si/III-V facet; and FIG. 18D includes images of a polished Si/III-V facet of a DFB QCL;

FIGS. 19A-19D shows active region cross-sections for preferred example laser structures;

FIG. 20 shows pulsed output power and voltage vs. injection current density for an experimental DFB QCL device of Design D with III-V tapers on both sides;

FIG. 21A-21D plots the light intensity vs. injection current density for experimental devices (two with Design A, two with Design B, four with Design C, and two with Design D);

FIGS. 22A-22D show slow-axis far field profiles for one laser of each active region design, at currents of 200, 350, 500, and 700 mA for Designs A-D, respectively;

FIGS. 23A-23D show normalized emission spectra at 20° C. of DFBs for designs A-D;

FIG. 24A shows measured peak wavelengths as a function of DFB grating pitch for all four lasers of Design C, from the spectral data of FIG. 25C;

FIG. 24B shows the measured wavelengths of the strongest peak, as a function of calculated Bragg wavelength, from the spectral data of FIGS. 23A-23D.

FIG. 25A shows pulsed output power for a laser of Design B at temperatures ranging from 10° C. to 100° C.;

FIGS. 25B-C shows threshold current density and differential efficiency, vs. temperature for a laser of Design B at temperatures ranging from 10° C. to 100° C.

FIGS. 26A and 26B show temperature-dependent emission spectra for the same laser of Design B whose temperature-dependent L-I characteristics are shown in FIG. 27;

FIGS. 27A and 27B compare a COMSOL simulation of the heat profile in a 6 μm-wide quantum cascade laser ridge grown on a native lattice matched InP substrate to a laser of the invention on a silicon substrate;

FIG. 28 plots the simulated maximum temperature in the structures as a function of injection current (or dissipated power);

FIG. 29 shows a plot of maximum operating temperature versus emission wavelength for quantum cascade lasers; and

FIG. 30 shows the band diagram of the coupled quantum wells of an example unipolar device.

### DETAILED DESCRIPTION OF THE PREFERRED EMBODIMENTS

Embodiments of the invention provide unipolar light emitting devices such as QCLs integrated with a foreign substrate. Foreign substrates include, but are not limited to, silicon, germanium, or sapphire. Compared to native III-V substrate integrations, unipolar light devices of the invention provide any or all of the following benefits: substantially lower manufacturing cost due to the lower cost of the foreign substrate, improved operation lifetime due to a higher thermal conductivity of the foreign substrate, improved mechanical durability due to higher hardness of the foreign substrate, and improved potential for integration. A particularly preferred embodiment, where the foreign substrate is silicon, can simultaneously provide all of these benefits.

Preferred silicon embodiments include bulk silicon substrates, such as a conventional silicon wafer, with no additional layers or materials. Embodiments also include layered foreign substrates where additional layers have been deposited on or bonded to a bulk foreign substrate. An example of such a layered foreign substrate includes silicon-on-insulator (SOI), where a silicon device layer sits above a silicon dioxide (SiO₂) layer above a silicon substrate. Other examples include silicon-on-nitride (SON), germanium-on-silicon (GOS), germanium-on-silicon-on-insulator (GOSOI), silicon-on-nitride-on-insulator (SONOI), and silicon-on-sapphire (SOS).

Preferred embodiments include both unprocessed foreign substrates and foreign substrates which have patterns transferred to the surface prior to integrating the unipolar light emitting device. One such pattern is a waveguide. Other patterns include various types of grooves, such as v-grooves, to aid in either blanket or selective-area epitaxial growth.

Preferred embodiments include devices integrated by epitaxial growth on a foreign substrate and devices integrated heterogeneously bonding.

Preferred embodiment unipolar light emitting devices provide simultaneous improvement of performance/reliability compared to integrations on native Group III-V substrates while also reducing the cost of unipolar light emitting devices such as quantum cascade lasers. By eliminating the need to integrate with lattice matched native III-V substrates, and instead integrating with foreign substrates, such as large area silicon substrates, the substrate cost for the growth of III-V quantum cascade lasers can be substantially reduced (in preferred embodiments where a unipolar device is epitaxially grown and fabricated directly on a foreign substrate). Furthermore, the significantly higher thermal conductivity of the silicon substrate (˜130 W/(m−K)) compared to GaAs (˜52 W/(m−K)), InP (˜68 W/(m−K)), or GaSb (˜32 W/(m−K)) provides better heat dissipation from the quantum cascade laser in preferred embodiments, which is a significant limiting factor in prior device performance. The heat dissipation with silicon is 2-4 times higher than III-V substrates in terms of conducting heat away from active device layers (while Ge does not provide a significant heat transfer advantage). Heat dissipation is provided in epitaxially grown integrated embodiments, and also in heterogeneously bonded embodiments. For example, in an embodiment with a QCL bonded to SOI, the insulating SiO₂ layer attenuates the thermal benefits compared to bulk Si. In another embodiment, a QCL is grown on SOI rather than bulk Si, and in that case the thermal benefit would also be attenuated. In addition, the silicon and germanium substrates are an order of magnitude cheaper in terms of cost per area, are non-toxic, and have excellent mechanical durability.

The present inventors have recognized an important issue that has perhaps inhibited artisans from integrating unipolar light devices with foreign substrates. When a crystalline III-V material is epitaxially grown on a foreign substrate which does not have the same lattice constant, defects are introduced into the III-V material due to the lattice mismatch. A problem with the mismatch and defects is that the defects act as carrier traps. With electron hole recombination, the carrier trapping has a significant negative impact on device performance because both electrons and holes are injected into the device and the free electron and hole populations are roughly equal in the active region due to space charge neutrality. The present inventors have recognized, however, that the impact with a unipolar light device is largely avoided. Quantum cascade lasers have relaxation times on the order of a few picoseconds or less, while the nonradiative recombination lifetimes of a typical conventional laser with a defect density of ˜10⁸/cm² is on the order of a nanosecond. The present inventors have recognized that these radiative relaxations are therefore expected to dominate even in the presence of extended defects in a quantum cascade laser of the invention integrated with silicon.

Because of this underlying difference in operating principle, unipolar light emitting devices such as quantum cascade lasers in accordance with the invention have a much greater immunity to the degradation and failure mechanism associated with defects in conventional light emitters, typically termed “recombination enhanced defect reactions”. Preferred embodiments provide unipolar light emitting devices, such as QCLs, deposited on or bonded to a foreign substrate, such as silicon, which will provide any or all of the improvements listed above including: substantially lower manufacturing cost, improved operation lifetime due to the higher thermal conductivity, improved mechanical durability, and integration with other photonic devices.

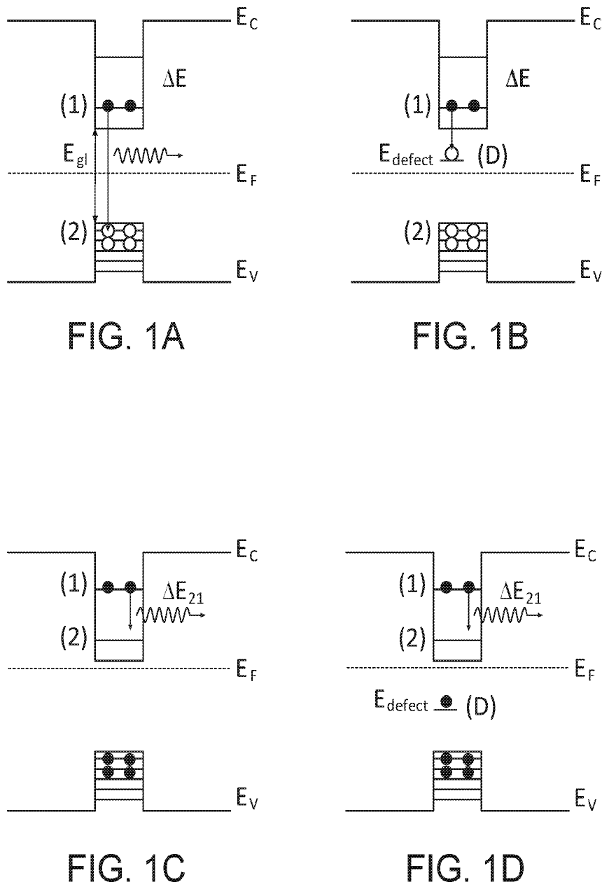

Spatially, crystalline defects may still act as carrier traps in a unipolar light emitting device of the invention integrated with a silicon substrate. Unlike electron hole recombination devices, though, the unipolar light emitting devices include an active region minority carrier population that is exceedingly small (comparable to the intrinsic carrier population) because only the majority carrier type is intentionally injected. Non-radiative recombination at defects, which requires both electrons and holes, is therefore correspondingly orders of magnitude less in a unipolar light emitting device of the invention compared to an electron hole recombination device integrated with silicon. A second degree of isolation between the radiative and nonradiative transitions arises electronically for typical defects in a III-V semiconductor laser, which lie within the forbidden gap of the material, and is illustrated in FIGS. 1A-1D. Intentional injection of one carrier type can be favored by engineering the fermi level and/or quasi fermi level throughout the entire structure to be near the conduction band with n-type dopants (where the desired majority carriers are electrons) or near the valence band with p-type dopants (where the desired majority carriers are holes). Where electrons are the majority carrier type for example, due to the quantum mechanical transition rules, electrons injected into the higher states of a quantum well are forbidden from transitions involving states below the fermi level which are already filled with electrons. The photon emitting intersubband transition process is therefore unperturbed by the existence of a defect level within the forbidden band gap, unlike the case of conventional interband light emitters. Specifically, FIG. 1A shows an electron in the conduction band combining with a hole in the valence band to emit a photon. This is an example of radiative recombination in a typical electron-hole recombination device which is not unipolar. FIG. 1B shows the same kind of a device, but where a defect state exists within the band gap. The electron in this case nonradiatively recombines with a hole in the defect state within the band gap rather than recombining with a hole in the valence band. FIG. 1C shows an electron transition between intersubband states in the conduction band, which emits a photon. This is an example of radiative emission from a unipolar device. FIG. 1D shows the same transition occurring with the presence of a defect state within the band gap. Because the defect state is below the fermi level and it is occupied by an electron a transition of an electron from the conduction band into the defect state cannot occur. Therefore, as illustrated in FIG. 1D, the intended electron transition occurs as in FIG. 1C, which is radiative and emits a photon.

Preferred embodiment unipolar light emitting devices are integrated with silicon or germanium substrates. Preferred devices include epitaxial Group III-V device layers grown on a silicon surface or a germanium surface, or an oxide thereof. The layers are selected and arranged such that light emission is achieved via intersubband transitions of a single type of carrier in either the conduction band or valence band. In preferred embodiments the Group III-V device layers include layers of (InₓAl_{y}Ga_{z})_{0.5}(AsᵤPᵥN_{w})_{0.5}, where x+y+z=1, u+v+w=1. In preferred embodiments, the intersubband transitions are between levels of a quantum well, a quantum wire or a quantum dot. Preferred devices include a quantum cascade laser. In preferred devices, the emission wavelength is in the range of ˜1-500 μm. Preferred devices provide a 1.3 μm emission and others a 1.55 μm emission. Other preferred devices provide emission within the mid-infrared region, ˜2-20 μm. Preferred devices include a silicon or germanium waveguide on the silicon substrate that guides the emitted light.

Preferred embodiments provide integration via epitaxial growth. One complication which arises from the epitaxial growth of light emitting materials on silicon is that the foreign light emitting materials typically have various degrees of lattice, polarity, and thermal expansion mismatch with the silicon substrate, and as a result crystalline defects are formed during the deposition process to accommodate the mismatch. These general classes of crystalline defects have an associated energy level which often resides within the bandgap of the host material. In a conventional light emitter, which relies on the recombination of an electron in the conduction band with holes in the valence band, these defect states can trap either one or both types of carriers at the defect level, robbing carriers away from desired radiative recombination to reduce the overall device efficiency. Furthermore, one of the main degradation modes of these light emitting materials is the growth or movement of existing defects during device operation, in which two types of carriers recombine at a defect state (Shockley-Read-Hall recombination), and the energy released from the recombination contributes to the continual propagation or growth of the existing defect.

However, the present unipolar light devices perform in a dramatically different fashion that is not as susceptible to the degradation. The inventors have realized, for example, that in the normal operation mode of a QCL, only one type of carrier is active (typically electrons) and transport is confined to one side of the bandgap only, and as a result the defects will not degrade performance in a similar manner to diode lasers. Electrons are typically injected into one of the quantum confined states of a quantum well within the conduction band active region. Light emission occurs when electrons relax into a lower quantum confined state within the active region. In the case of a quantum cascade laser, electrons can be recycled many times via resonant tunneling from a lower state of one well into an adjacent well's excited state and subsequent relaxation into another lower state, in the process producing N photons where N is the number of cascaded stages. Thus, an electron can still contribute to positive gain and photon generation if it is not lost to a defect in the first stage.

Spatially, crystalline defects may still act as carrier traps in the present unipolar light emitting device. In conventional light emitters, both electrons and holes are injected into the device and the free electron and hole populations are roughly equal in the active region due to space charge neutrality. The distinction with unipolar light emitting devices is that the active region minority carrier population is exceedingly small (comparable to the intrinsic carrier population) because only the majority carrier type is intentionally injected. Non-radiative recombination at defects, which requires both electrons and holes, is therefore correspondingly orders of magnitude less in a unipolar light emitting device. A second degree of isolation between the radiative and nonradiative transitions arises electronically for typical defects in a III-V semiconductor laser which lie within the forbidden gap of the material, and is illustrated in FIGS. 1A-1D. FIGS. 1A and 1B show a conventional light emitter where both electrons and holes are injected into the device. FIGS. 1C and 1D show a unipolar light emitting device where only electrons are intentionally injected into the device. In FIG. 1A, the electron in the conduction band at level (1) radiatively recombines with the hole in the valence band at level (2) to emit a photon. In FIG. 1B, a defect state is present within the band gap and the electron in level (1) instead recombines with the hole in the defect state within the band gap at level (D). In FIG. 1C, an electron transition from an upper energy state within the conduction band at level (1) to a lower energy state within the conduction band at level (2) emits a photon. In FIG. 1D, the same electron transition occurs, even with the presence of a defect state at level (D) within the band gap. Intentional injection of one carrier type can be favored by engineering the fermi level and/or quasi fermi level throughout the entire structure to be near the conduction band with n-type dopants (where the desired majority carriers are electrons) or near the valence band with p-type dopants (where the desired majority carriers are holes). Where electrons are the majority carrier type for example, due to the quantum mechanical transition rules, electrons injected into the higher states of a quantum well are forbidden from transitions involving states below the fermi level which are already filled with electrons, illustrated in FIGS. 1A-1D. The photon emitting intersubband transition process is therefore unperturbed by the existence of a defect level, unlike the case of conventional interband light emitters.

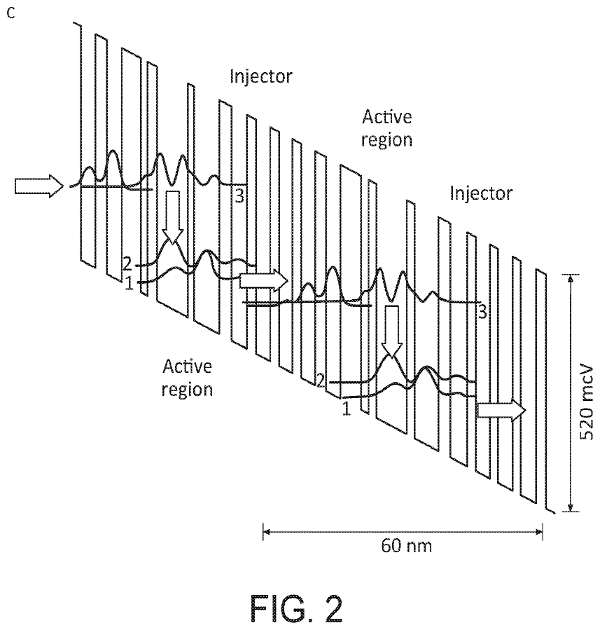

FIG. 2 shows a simplified schematic of the conduction band structure for a quantum cascade laser. Typical relaxation times for a conventional quantum cascade laser integrated with a native substrate, for example, are: ˜4.3 ps between subbands 3 and 2 (where radiative emission occurs); ˜0.6 ps between subbands 2 and 1 (to achieve population inversion); and ˜≤0.5 ps between subband 1 and subband 3 of the adjacent well (resonant tunneling of the electron through the injector into the excited state of the next active region stage for electron recycling). These time scales are 1000 times faster than the typical non-radiative recombination lifetimes in a conventional laser, typically on the order of a nanosecond for a defect density of ˜10⁸/cm² which is typical of III-V growth on silicon. The present inventors have realized that these radiative relaxations can dominate even in the presence of extended defects, and therefore not suffer the level of degradation that a conventional laser would suffer.

Because of this underlying difference in operating principle, unipolar light emitting devices of the invention are substantially immune to the degradation and failure mechanisms associated with defects in conventional light emitters—typically termed “recombination enhanced defect reactions.” The prevalent failure mode in a conventional QCL fabricated on a native substrate is excessive heating and subsequent melting of the material.

Preferred embodiments of the invention will now be discussed with respect to the drawings and experiments that demonstrate principles of the invention. Applications and broader aspects of the invention will be understood by artisans in view of the general knowledge in the art and the description that follows.

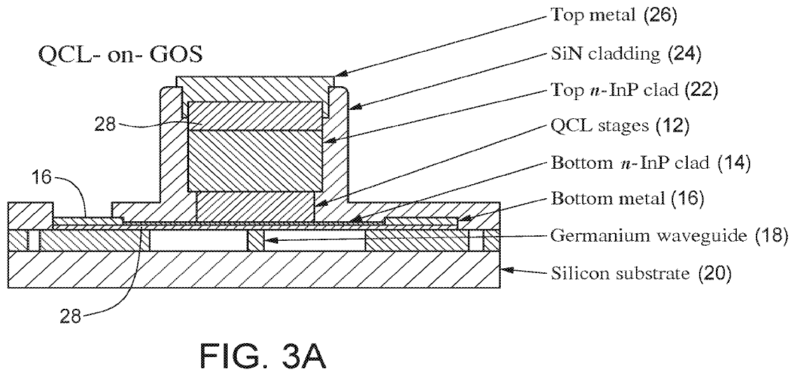

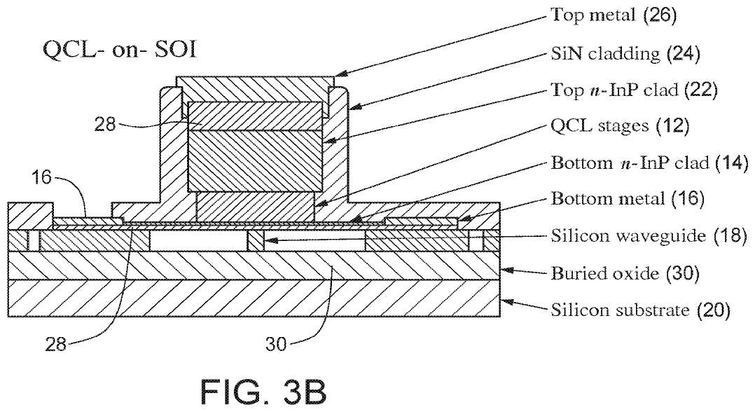

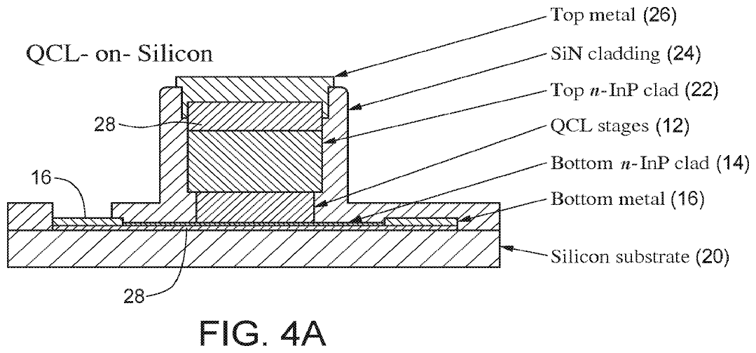

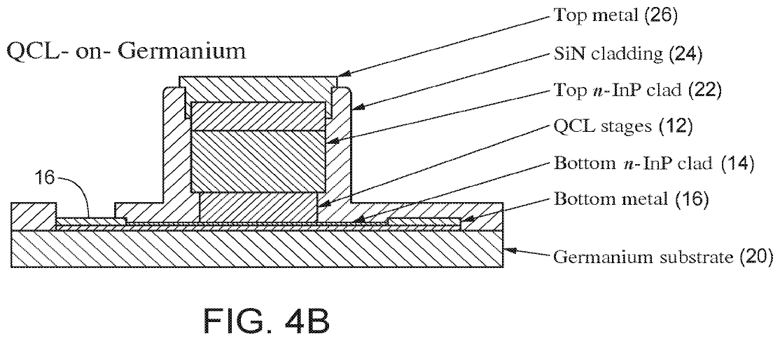

FIGS. 3A-4B illustrate a preferred embodiment quantum cascade lasers on foreign substrates, shown in cross-section. In each of the FIG. 3A-4B embodiments, QCL active layers 12 are clad by bottom InP cladding 14 and contact layers 28 that are formed upon a foreign layer 18 integrated with a foreign substrate 20. Top and bottom cladding layers 22 and 14 and contact layers 28 surround the active region. The distinction is that the contact layers 28 are doped higher and suitable for metal to be deposited on them. In FIG. 3A, the foreign layer 18 is a germanium waveguide layer on a silicon substrate. The FIG. 3A embodiment is especially well-suited as a higher power device, and will be capable of higher power than other preferred embodiments. The germanium layer 18 can be bonded, deposited, or epitaxially grown on the silicon substrate 20 before a waveguide is lithographically defined and etched in the Ge layer 18. In FIG. 3B, the foreign layer 18 is a silicon waveguide layer separated by an oxide layer 30 on a silicon substrate 20. This configuration is typically referred to as silicon-on-insulator (SOI). In FIG. 4A, the foreign layer is the surface of the foreign silicon substrate 20. In FIG. 4B, the foreign layer is the surface of the foreign germanium substrate 20. For any of the structures in FIGS. 3A-4B, a waveguide can be defined in the silicon, SOI, GOS, germanium etc., before the QCL growth steps or before the buffer layer growth steps. For any of these options, the QCL or unipolar laser structure can vary. It can be optically pumped or electrically pumped and it can be electrically pumped laterally or vertically. It can be optimized for light emission at any wavelength. The laser layers and thicknesses can be tailored to match the desired pumping scheme.

The FIG. 3A-4B embodiments are examples of preferred embodiments where the Group III-V device layers are directly interfaced upon the foreign layer via either epitaxial growth on the foreign layer or bonding. The FIG. 3A-4B embodiments illustrate silicon or germanium substrates which are either patterned with silicon waveguides or unpatterned. Substrates patterned with grooves can also be used, such as disclosed in Wan et al. in the Background section above. The groove-patterned substrates reduce the density of defects in the III-V layers, though the defects do not impact device performance to the extent that defects do in the diode lasers disclosed in Wan et al. Similarly, selective area growth can be applied to reduce defects as disclosed by Wang et al. in the Background section above.

Many types of unipolar emission devices are within the scope of the invention, as will be appreciated by artisans. The invention is not limited by specific growth conditions or layer thicknesses for the unipolar emission device or QCL. Example preferred embodiments include an InP-based Quantum Cascade Laser (QCL), a GaAs-based QCL, and an InP-based or GaAs-based unipolar laser which is not a QCL integrated with a foreign substrate.

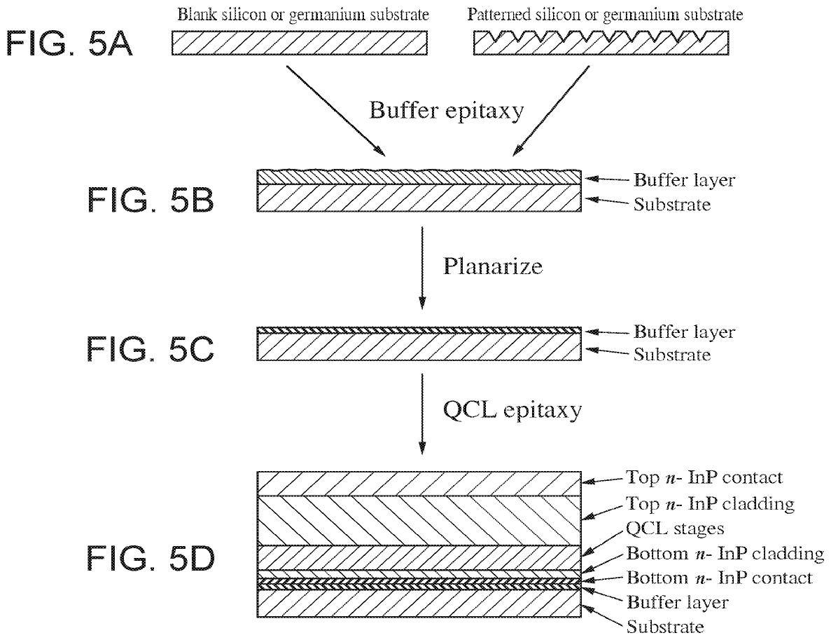

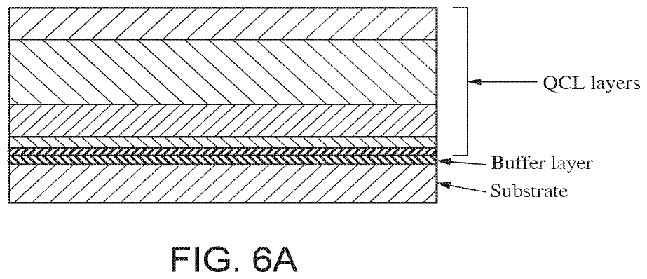

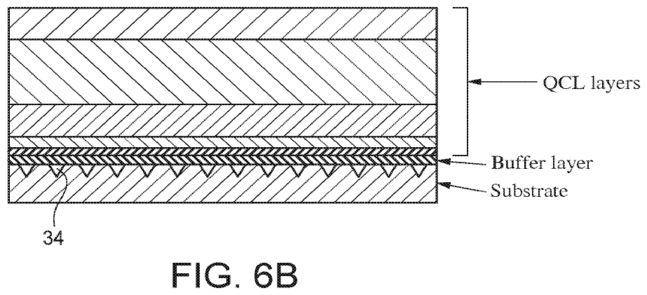

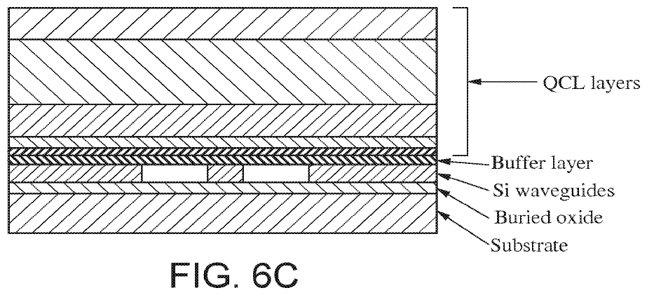

FIGS. 5A-5D illustrate a preferred embodiment fabrication process. The process begins in FIG. 5A with a foreign substrate, which can be patterned or not and which can have waveguides defined or not. A buffer layer may or may not be epitaxially grown on the substrate. The preferred buffer layer, if used, can comprise of any III-V materials and the composition will be dependent on growth conditions, the unipolar emitter, the foreign substrate material, and additional factors. An optional polishing (CMP, chemical-mechanical polishing) step, shown in FIG. 5C, can be employed after the initial buffer epitaxial growth to planarize the buffer layer. In FIG. 5D, epitaxial growth processes are used to form a QCL. FIGS. 6A-6C illustrate variations of the fabrication process. In FIG. 6A, the buffer layer is formed directly on the foreign substrate, which is not patterned. In FIG. 6B, the buffer layer is formed directly on the foreign substrate, which includes a v-groove pattern 34. In FIG. 6C, the buffer layer is formed on a waveguide, which is foreign to the light emitter layers.

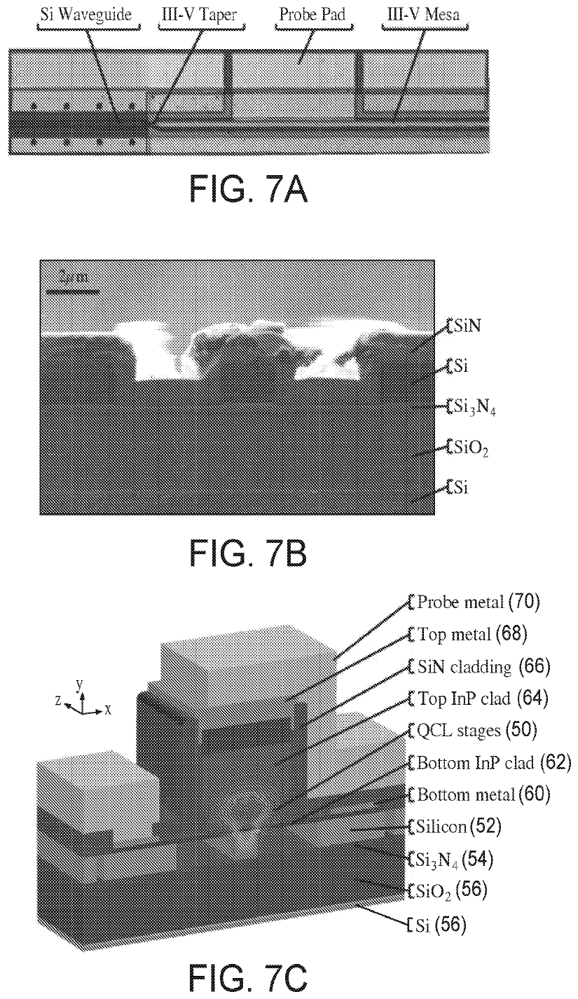

FIGS. 7A to 7C illustrate a preferred embodiment quantum cascade laser heterogeneously integrated on silicon with a silicon-on-nitride-on-insulator (SONOI) ultra-broadband waveguide platform. This example embodiment is an example of a QCL integrated on a silicon substrate by bonding, rather than by epitaxial growth. Example QCLs in accordance with FIGS. 7A-7C emit 4.8 μm light at room temperature in pulsed operation. FIG. 7A is an optical microscope image of an integrated QCL. FIG. 7B shows the polished SONOI waveguide end-facet of an integrated QCL. FIG. 7C shows a cross-sectional schematic of a hybrid silicon-QCL active region. A contour plot of the electric field component, |E_{y}|, of the simulated fundamental TM optical mode is overlaid.

In experiments, each laser consisted of a 4 mm long hybrid silicon-QCL active region FIG. 7C coupled to passive silicon waveguide regions at each side. Tapered III-V mesas are designed to couple light between the hybrid silicon-QCL mode and a passive silicon waveguide mode. A Fabry-Pérot cavity is then formed by uncoated, polished silicon waveguide facets, as seen in the scanning electron microscope (SEM) image in FIG. 7B. While not shown, feedback from gratings (DFB or DBR) or loop mirrors can be incorporated. See A. Spott, et al., “Heterogeneously Integrated Distributed Feedback Quantum Cascade Lasers on Silicon,” Photonics, vol. 3, no. 2, p. 35, (June 2016). This has previously accomplished at shorter wavelengths. See, Komljenovic, S. et al., “Widely Tunable Narrow-Linewidth Monolithically Integrated External-Cavity Semiconductor Lasers,” IEEE J. Sel. Top. Quantum Electron. 21, 1501909 (2015) and C. Zhang, et al, “Low threshold and high speed short cavity distributed feedback hybrid silicon lasers,” Opt. Express, vol. 22, no. 9, pp. 10202-10209 (May 2014).

A cross-sectional schematic of the hybrid silicon-QCL region is shown in FIG. 7C. The hybrid silicon-QCL region geometry is designed to support light in the transverse magnetic (TM) polarization emitted by QCLs. The silicon waveguide 52 is on a Si₃N₄ cladding 54 layer on top of a foreign SiO₂ layer 56, which is upon a silicon substrate 58. The mesa structure is completed with bottom metal 60, bottom and outer InP cladding, the active stages 50 and top InP cladding 64, top SiN cladding 66, top metal 68 and probe metal 70. A simulation from FIMMWAVE of the fundamental TM mode, which is shared between the narrow silicon waveguide and the InP QCL ridge waveguide, is shown projected onto the active region cross-section schematic. Mode solver simulations find the transverse confinement factor f in the QCL active core, which depends on both the III-V mesa and silicon waveguide widths, to be between 0.6 and 0.75 for fabricated devices, although the optical confinement can be engineered outside of this range. The silicon waveguides in the experimental devices are 1.5 μm tall. The III-V mesas for two experimental Devices A and B are 6 μm wide and their silicon waveguides in the active region are 1 μm and 1.5 μm wide, respectively. The silicon waveguides expand to 6 μm wide underneath the III-V tapers, and are 2 μm wide in the passive silicon regions. Device A has a 20 μm long III-V tapers while Device B has a 45 μm long III-V taper.

Prior to bonding above the silicon waveguides which are on a silicon substrate, the QCL material was grown by metalorganic chemical vapor deposition (MOCVD), with 30 active stages on an InP substrate. The surrounding layers, modified for heterogeneous integration on silicon, are shown in Table 1. A thick top InP cladding separates the optical mode from the contact metal, while a thin InP bottom cladding keeps the active region close to the silicon for improved efficiency of the taper mode conversion.

TABLE 1
III-V Layers

| | | Thickness | Doping |
|---|---|---|---|
| Layers | Material | (nm) | (cm⁻³) |
| Substrate | InP | — | — |
| Etch stop | InGaAs | 50 | — |
| Top contact | n-InP | 1500 | 5 × 10¹⁸ |
| Top clad | n-InP | 50 | 5 × 10¹⁷ |
| Top clad | n-InP | 50 | 1 × 10¹⁷ |
| Top clad | n-InP | 2450 | 2 × 10¹⁸ |
| Transition | n-InGaAs/InAlAs | 50 | 1 × 10¹⁷ |
| Active core | n-QC structure | 1510 | Variable |
| Transition | n-InGaAs/InAlAs | 50 | 1 × 10¹⁷ |
| Bottom clad | n-InP | 50 | 1 × 10¹⁷ |
| Bottom clad | n-InP | 50 | 5 × 10¹⁷ |
| Bottom contact | n-InP | 200 | 1 × 10¹⁸ |
| Bonding SL | n-InP | 7.5 | 1 × 10¹⁸ |
| Bonding SL | n-InGaAs | 7.5 | 1 × 10¹⁸ |
| Bonding SL | n-InP | 7.5 | 1 × 10¹⁸ |
| Bonding SL | n-InGaAs | 7.5 | 1 × 10¹⁸ |
| Bonding layer | n-InP | 10 | 1 × 10¹⁸ |
| Capping layer | n-InGaAs | 200 | 1 × 10¹⁸ |

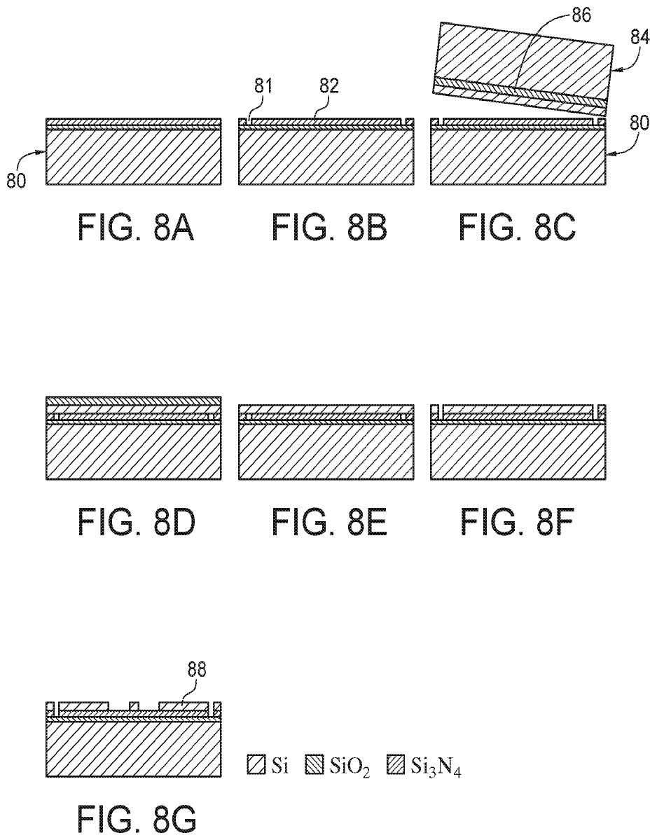

FIGS. 8A-8G shows a preferred fabrication process for a SONOI chip which is a multilayer foreign substrate suitable for integration with a unipolar light emitting device and heterogeneously integrated with a QCL in experiments. FIG. 8A begins with a nitride-on-insulator (NOI) chip 80 which is composed of a Si₃N₄ layer above an SiO₂ layer above a silicon substrate. FIG. 8B shows a dry etch of the vertical outgassing channels 81 through a Si₃N₄ layer 82 and into the SiO₂. FIG. 8C shows a bond of a SOI chip 84 to the NOI chip. FIG. 8D shows removal the Si substrate from the bonded SOI chip. FIG. 8E shows removal of its SiO₂ layer 86 with buffered HF. FIG. 8F shows a dry etch of the vertical outgassing channels in the Si device layer for later QCL bonding. FIG. 8G shows a dry etch to produce the strip waveguides 88. In experiments, the NOI wafer consisted of a silicon substrate with a 3 μm thermally grown SiO₂ layer and 400 nm stoichiometric Si₃N₄ layer deposited on both the top and bottom of the silicon wafer. The SOI wafer consisted of a 1.5 μm Si device layer, a 1 μm buried SiO₂ (BOX) layer, and a Si substrate. During the process, vertical outgassing channels (VOCs) are etched through the Si₃N₄ and SiO₂ layers of the NOI chip. An SOI chip is then bonded after a plasma surface activation. The resulting chip is annealed in a graphite bonding fixture at 300° C. for 2 hours, then further annealed in a tube furnace at 900° C. for 4 hours (with a 600° C. overnight idling). After bonding, the Si substrate is removed from the SOI chip by mechanical lapping and an inductively coupled plasma (ICP) C₄F₈/SF₆/Ar etch, whose rate slows once it reaches the SiO₂. The SiO₂ layer is then removed with buffered HF to leave the SONOI chip. Finally, VOCs for QCL bonding and the strip waveguides are fully etched with C₄F₈/SF₆/Ar ICP etches.

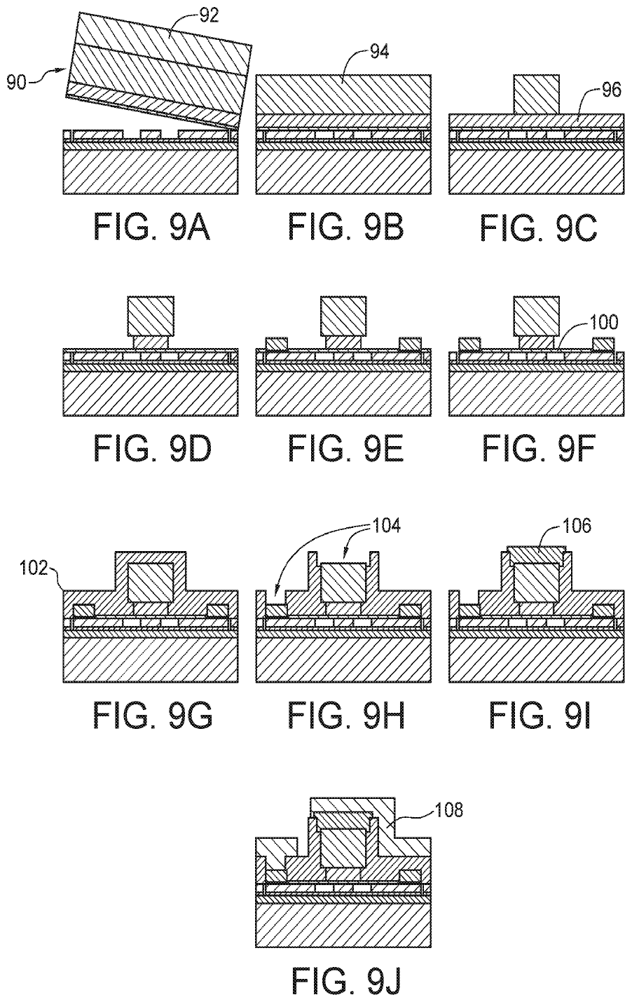

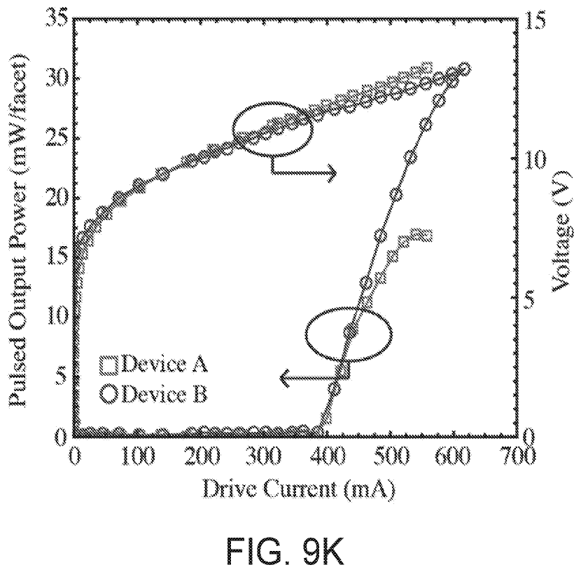

FIGS. 9A-9J illustrate steps to fabricate integrated QCLs. FIG. 9A bond QCL material to the SONOI chip on the silicon waveguide 88. FIG. 9B, remove the InP substrate 92. FIG. 9C, dry etch the top InP cladding 94. FIG. 9D, wet etch the QCL active stages 96. FIG. 9E, deposit n-metal for the bottom contact. FIG. 9F, dry etch the bottom InP cladding 100. FIG. 9G, deposit a SiN cladding 102 by PECVD. FIG. 9H, dry etch vias 104. FIG. 9I, deposit n-metal 106 for the top contact. FIG. 9J, deposit probe metal 108. The QCL fabrication process begins by flip-chip bonding the QCL material to the SONOI chip after removing the capping layer (with an H₃PO₄:H₂O₂:DI 1:1:38 wet etch) and plasma activation. The InP substrate is removed by mechanical lapping and an HCl:DI 3:1 wet etch that selectively stops on an InGaAs etch stop layer. The QCL mesa is defined with an SiO₂ hard mask. The InP top cladding is etched with a CH₄/H₂/Ar reactive ion etch (RIE) and stopped at the QCL active region with laser endpoint detection. The QCL active region is removed with an H₃PO₄:H₂O₂:DI 1:5:15 wet etch. To reduce undercutting of the QCL layers, this etch is performed in multiple steps consisting of repeated stripping and re-patterning of the photoresist. Pd/Ge/Pd/Au (10/110/25/1000 nm) is deposited for both the top and bottom contacts. Before the bottom contact metal is deposited, the bottom cladding is etched with a short RIE to reveal the 200 nm, highly doped InP bottom contact layer. 1200 nm PECVD SiN is deposited as an electrical isolation layer, and vias are etched prior to depositing the top contact and probe metals. Laser bars are diced from the chip and the SONOI facets are mechanically polished.

Experiments tested lasers in accordance with FIGS. 7A-9J. After fabrication, the silicon laser bar substrate was bonded with GE varnish to a copper sub-mount and the probe pads were contacted with wire bonds to inject current. The lasers were driven with a pulsed current source that produced 250 ns wide pulses at a 1 kHz repetition rate for all of the measurements. The light output was collected with an f/1 aspheric ZnSe lens and focused onto a fast room temperature HgCdTe detector with an f/2 aspheric ZnSe lens. Digitized scope readings were averaged from 150-200 ns to measure the detector voltage. A direct calibration of the measured detector voltage was obtained by operating the device at 200 kHz and measuring the output with both the above described collection and detection, and also with a 25 mm diameter thermopile detector placed directly at the device output.

FIG. 9K shows single-sided optical output power and voltage vs. drive current of two integrated QCLs. The L-I-V characteristics for operation in pulsed mode at room temperature were measured for 10 integrated QCLs of varying geometries. Despite quantitative variations, the results are generally consistent qualitatively. FIG. 9K plots the characteristics of two of the better lasers at 20° C. The threshold currents are 388 mA and 387 mA for Devices A and B, respectively, while the maximum output powers are 17 mW and 31 mW. The slope efficiency near threshold for Device A is 150 mW/A, while for Device B it is 170 mW/A. The maximum wall-plug efficiency for Device B (from one of the two uncoated SONOI facets) is 0.35%.

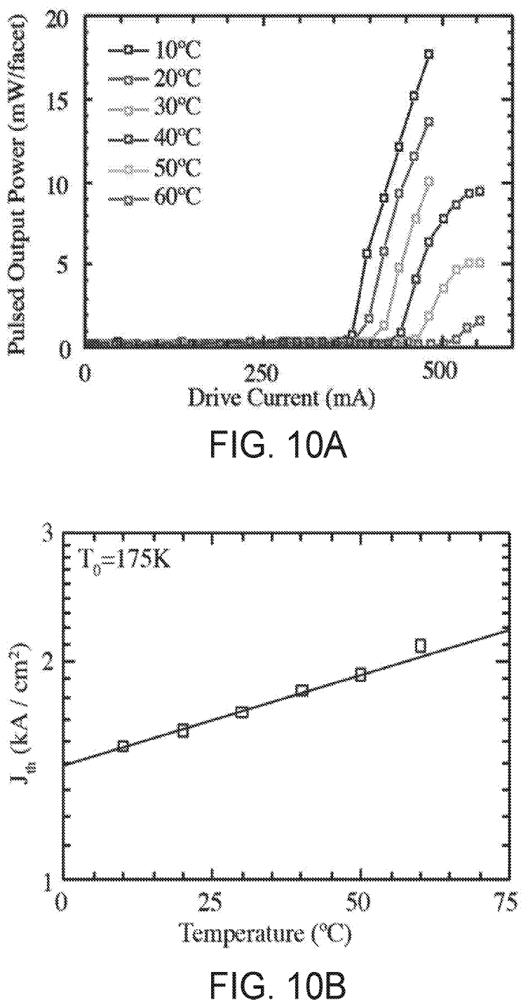

FIG. 10A shows single-sided output power vs. drive current for Device A at temperatures from 10° C. to 60° C. FIG. 10B shows corresponding threshold current densities vs. temperature. The fit yields a characteristic temperature of T₀=175 K. FIG. 10A shows the output power emitted from Device A at a series of temperatures ranging from 10 to 60° C. FIG. 10B plots the corresponding temperature dependence of the threshold current density obtained by dividing the threshold current by the III-V active area. The characteristic temperature T₀ was found to be 175 K by fitting the exponential function Jₜₕ=J₀exp(T/T₀). This is a typical value as far as pulsed characteristic temperatures for relatively low-injector-doping, 4.5-5.0 μm-emitting QCLs as needed for low-power-dissipation applications. A fit of the slope efficiency vs. temperature yields T₁=87 K.

In these embodiments where the substrate is layered and includes SiO₂ and Si₃N₄ layers, the low thermal conductivity of the buried SiO₂ layer significantly impedes heat removal from the active region compared to the embodiments where a bulk silicon substrate is used. Layered substrates improve or impede heat removal from the active region depending on the thermal conductivities and thicknesses of the layers involved. However, poor heat dissipation is not a fundamental limitation of layered substrates where the substrate is silicon. Improvement is also possible in this bonded embodiment, such as through the introduction of thermal shunts. See, e.g., M. N. Sysak, et al, “Hybrid Silicon Laser Technology: A Thermal Perspective,” IEEE J. Sel. Top. Quantum Electron. 17, 1490 (2011). Another option is an epilayers-down arrangement wherein the top of the chip is bonded to a thermally conductive submount. In any of these cases, the cost, mechanical durability, and integration advantages of the silicon substrate are retained.

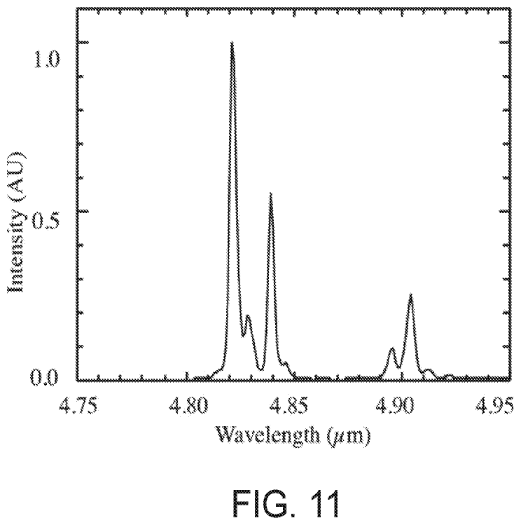

FIG. 11 shows the spectral emission from Device B at 20° C. The spectrum acquired with a Digikrom 0.5 m monochromator with 1.5 nm resolution indicates a peak wavelength of 4.82 μm.

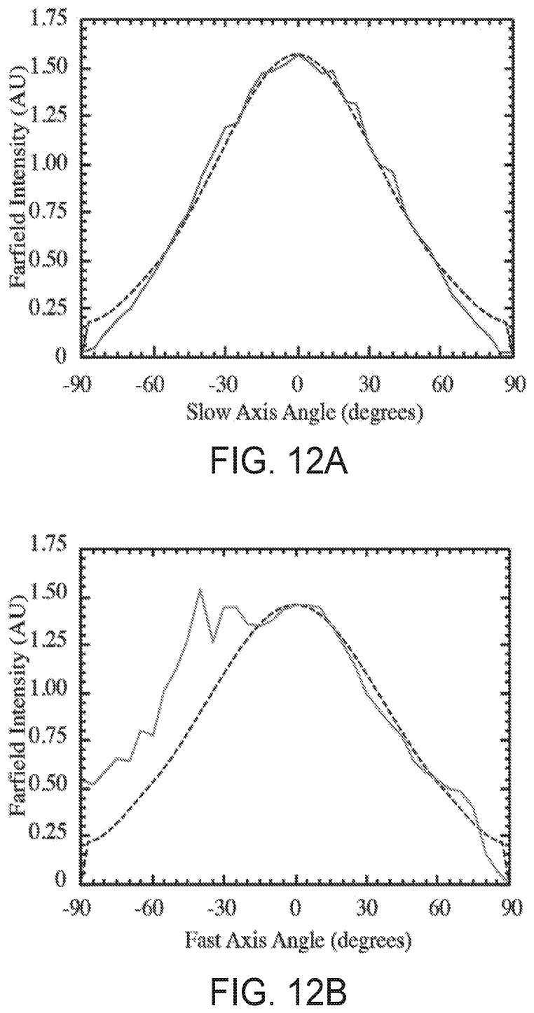

FIGS. 12A and 12B show far field intensity of Device A as a function of the angle normal to the facet in the slow (horizontal) axis (top) and fast (vertical) axis (bottom). Solid lines indicate measurements and dotted lines indicate simulated profiles. Measurements were taken at 20° C. and a drive current of 500 mA. The solid curves in FIGS. 12A and 12B show horizontal (FIG. 12A) and vertical (FIG. 12B) far-field profiles of the emission from Device A. A similar profile along the slow axis was obtained for Device B (which was not measured along the fast axis). The dashed lines in the figures are FIMMWAVE simulations corresponding to the fundamental TM mode of the passive SONOI waveguides. That the measured profiles agree well with the simulated shapes, particularly in the horizontal direction, indicates that the QCLs emit primarily in the fundamental TM mode. The additional features at negative angles below ˜−15 degrees along the fast axis are most likely due to polishing imperfections, such as residue on the SONOI facet or the surrounding cladding. According to the simulations, a higher-order transverse TM mode in the SONOI waveguide has strong optical overlap with the QCL core in the hybrid active region. Since that mode is expected to efficiently couple through the tapers into a higher-order mode in the passive silicon waveguide region, the far-field measurements imply that this higher-order mode does not reach the lasing threshold.

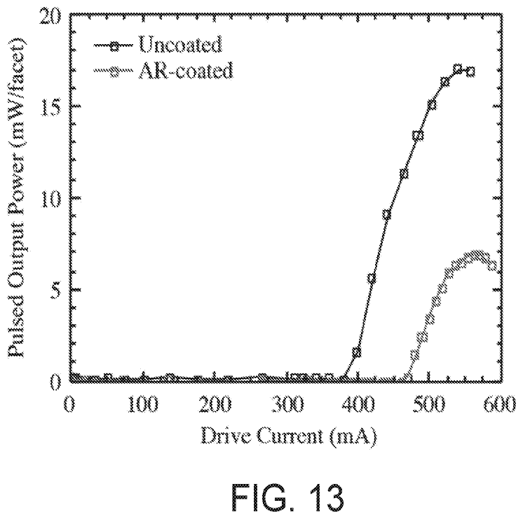

FIG. 13 shows Single-Sided Output power vs. drive current at 20° C. for Device A before and after depositing an AR coating on the SONOI waveguide facets. FIG. 13 compares the L-I curves for Device A before (black) and after (red) the AR coating was applied. The threshold is seen to increase only modestly (by 20%, to 466 mA) while the efficiency decreases from 153 mW/A to 89 mw/A (most likely because the threshold current is approaching the rollover regime). Consistent results were obtained for one other device that showed a similar threshold increase and a slight increase of the efficiency. Three other devices did not lase following AR coating of the output facet, probably because they operated too close to the rollover point.

Generally, the FIGS. 7A-7C devices exhibited threshold currents as low as 387 mA and single-sided output powers as high as 31 mW were observed for pulsed operation at 20° C. Improved heat dissipation is expected to enable CW lasing in the MIR. Bonding materials from different QCL wafers can enable devices emitting at a wide range of wavelengths to be heterogeneously integrated on the same silicon chip. Any III-V materials arranged with thicknesses, combinations, and orders selected to emit light can be used. Example Group III-V device layers include layers of (InₓAl_{y}Ga_{z})_{0.5}(AsᵤPᵥN_{w})_{0.5}, where x+y+z=1, u+v+w=1.

While internal reflections that depend on polished waveguide facets are not suitable for integration within a photonic integrated circuit, wavelength-selective feedback elements, which can be integrated with lasers in the NIR [Komljenovic, S. et al., “Widely Tunable Narrow-Linewidth Monolithically Integrated External-Cavity Semiconductor Lasers,” IEEE J. Select. Topics Quantum Electron., vol. 21, no. 6, p. 1501909, (November 2015)], can be applied at longer wavelengths. Bragg reflectors for the mid-infrared are easier to define with photolithography as the grating pitch required for a first-order grating scales with wavelength.

In embodiments where the unipolar light emitting device is integrated on a foreign substrate by bonding rather than epitaxial growth, the factors to adjust or consider during the bonding process depend upon the type of foreign substrate and the particular III-V material and include pressure, anneal temperature, anneal time, the substrate removal process, pre-cleaning procedures and plasma activation procedures.

QCL gain material has been used for amplification by others [S. Menzel, L. Diehl, C. Pflügl, A. Goyal, C. Wang, A. Sanchez, G. Turner, and F. Capasso, “Quantum cascade laser master-oscillator power-amplifier with 1.5 W output power at 300 K,” Opt. Express, vol. 19, no. 17, pp. 16229-16235, (August 2011)] and the same can be achieved on silicon according to the invention to construct integrated SOAs as was achieved at 2.0 μm. The active stages of a QCL can also be designed for operation at other wavelengths without significantly modifying the surrounding cladding layers. It is therefore possible to apply these techniques at longer or shorter wavelengths to provide laser sources throughout the MIR transmission window of Si waveguides, up to wavelengths near 7 μm.

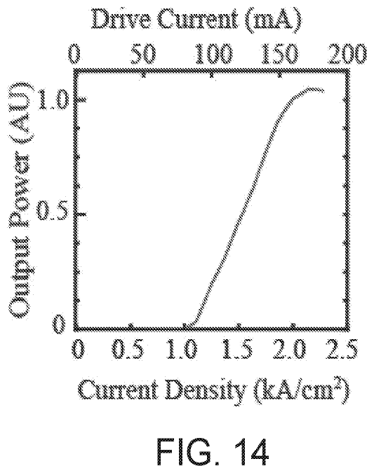

Smaller DFB lasers with lower threshold drive currents, e.g., with 2-mm long active regions, displayed similar threshold current densities of near 1 kA/cm². Specifically, FIG. 14 shows pulsed light emission vs. current density from a 2-mm long DFB QCL with a 4-μm wide narrow mesa region and 1.5-μm wide Si waveguide, showing a threshold current of 80 mA.

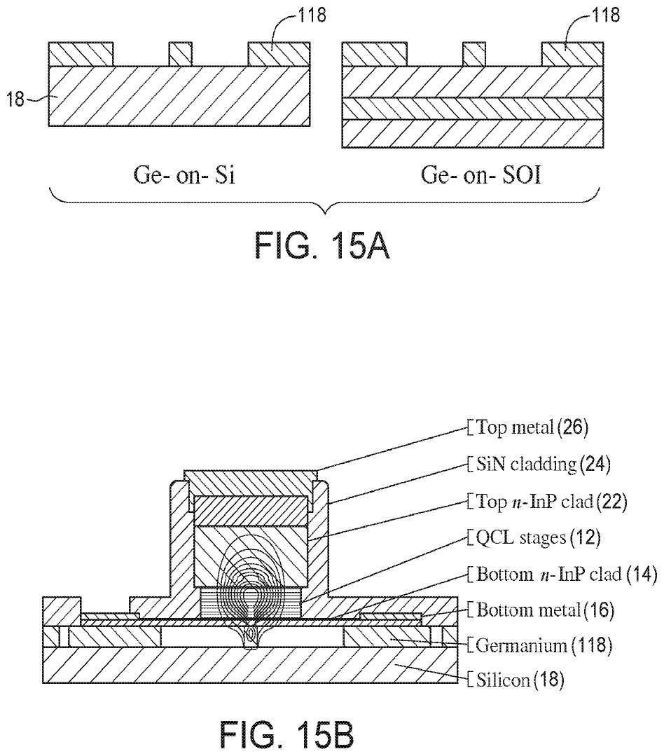

FIG. 15A shows two preferred options for placing a Ge waveguide 118 above a Si layer or substrate. FIG. 15A includes the cross-sectional schematic of Ge-on-Si and Ge-on-SOI waveguide platforms, with the FIG. 15A right stack having from top to bottom Ge waveguide 118, Si, SiO₂ and Si. FIG. 15B includes cross-sectional schematic labeled with previously used reference numbers and optical mode simulation of a QCL on a Ge-on-Si waveguide.

As with SOI and SONOI heterogeneous integration, low temperature, plasma-assisted, hydrophilic wafer bonding can be applied to bond QCL layers above GOS or GOSOI waveguides and achieve the FIG. 15B structure. The FIG. 15B hybrid GOS/III-V active region analogous to the QCL configuration shown in FIG. 7C. Overlaid is a contour plot of the electric field component |E_{y}| of the fundamental TM optical mode, which has a confinement with the active region of Γ ≈0.77. Due to the high refractive index of Ge, and therefore the high effective index of GOS waveguides, a slightly narrower Ge waveguide is necessary to push the optical mode higher into the QCL mesa. This high refractive index may allow more efficient III-V taper transitions.

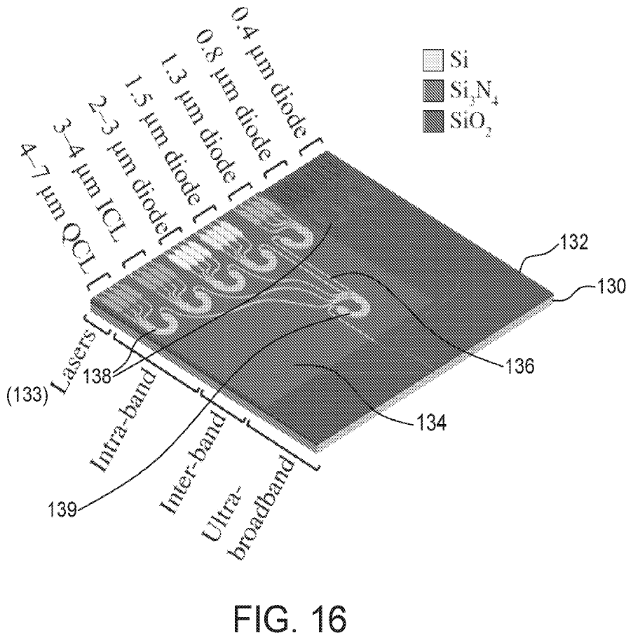

FIG. 16 shows a multi-spectral laser architecture with multiple gain materials bonded onto a Si substrate 130 with oxide 132 and Si₃N₄ 134, including QCL, ICL, and diode lasers 133. Each laser output is spectrally combined in multiple stages to a single output waveguide 136. The architecture provides a multispectral source integrated on a single SONOI platform that combines the beams from bonded III-V lasers emitting at wavelengths ranging from about 0.4 μm to about 7 μm. In a first (intra-band) combination stage, the light produced by arrays for each band is combined into one single output waveguide for each coarse wavelength band by AWGs (arrayed waveguide grating) 138. In the second (inter-band) combination stage (phase of beam combination), light from each spectral bands is combined with an AWG 139 designed to have a much coarser wavelength spacing. On a SONOI waveguide platform, the light at shorter wavelengths is generated in Si₃N₄ waveguides while the light at longer wavelengths (including the MIR) is generated in Si waveguides. Then in the final combination stage, an ultra-broadband duplexer is used to combine all channels [E. J. Stanton, et al., “Multi-octave spectral beam combiner on ultra-broadband photonic integrated circuit platform,” Opt. Express, vol. 23, no. 9, pp. 11272-11283, May 2015].

The heterogeneous integration with QCL lasers on foreign substrates according the invention allows multiple lasers (including diode lasers) operating at different wavelengths to be integrated on one chip, and spectral beam combining can be used to construct a multispectral light source [See, I. Vurgaftman, et al., U.S. Pat. No. 9,612,398, which is incorporated by reference herein]. For densely spaced spectral channels, arrayed waveguide gratings (AWGs) have been demonstrated with low loss spanning the visible (VIS) [E. J. Stanton, et al., “Low-loss arrayed waveguide grating at 760 nm,” Opt. Lett., vol. 41, no. 8, pp. 1785-1788, (April 2016)] to NIR [J. F. Bauters, et al., “Design and characterization of arrayed waveguide gratings using ultra-low loss Si3N4 waveguides,” Appl. Phys. A, vol. 116, no. 2, pp. 427-432, (June 2014)], and moderate loss in the MIR [M. Muneeb, et al., “Demonstration of Silicon-on-insulator mid-infrared spectrometers operating at 3.8 μm,” Opt. Express, vol. 21, no. 10, pp. 11659-11669, (May 2013)] [A. Malik et al., “Germanium-on-Silicon Mid-Infrared Arrayed Waveguide Grating Multiplexers,” Photonics Technology Letters, IEEE, vol. 25, no. 18, pp. 1805-1808, (September 2013).

There are options for aligning each laser emission wavelength to the AWG spectral combiner channel In one option, the lasers can be tuned to align with the combiner channel with a feedback that maximizes the output power. The AWG can also be tuned. A second option is to design the AWG within the laser cavity. This is typically avoided since it would compromise the performance of the lasers and result in lower output power and brightness. However, with AWGs having <0.5 dB of loss per channel, this may be advantageous when applied to a multi-spectral laser with many channels.

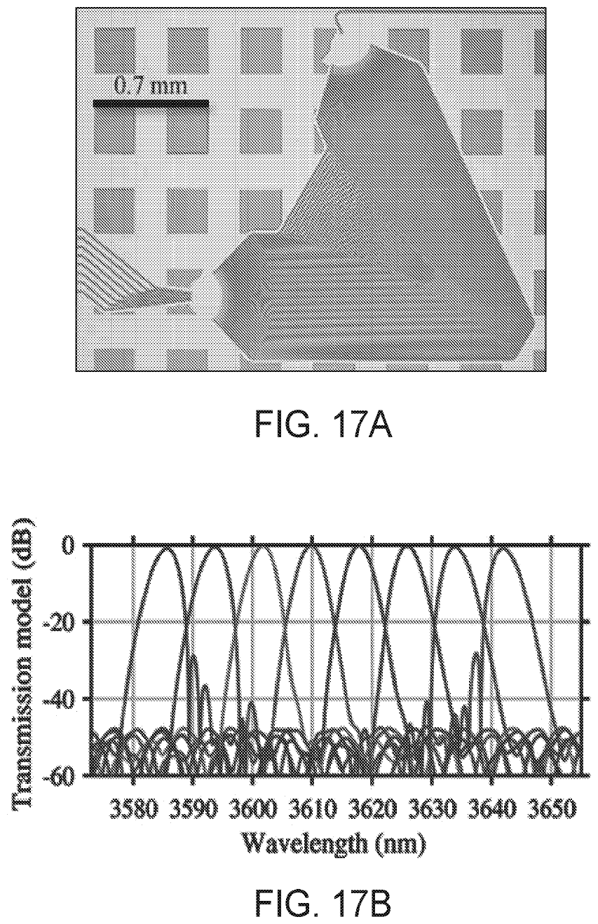

The loss in the spectral combiners should be less than about 3 dB per channel. The SOI-based AWGs are expected to provide such low loss for wavelengths up to ˜3.6 μm or higher. FIG. 17A shows a micrograph of an AWG fabricated on SOI and designed to have a center wavelength of ˜3.61 μm and channel spacing of ˜10 nm. The simulated transmission spectra shown in FIG. 17B demonstrates low loss in the range 0.2-1.0 dB, and a crosstalk of −45 dB per channel.

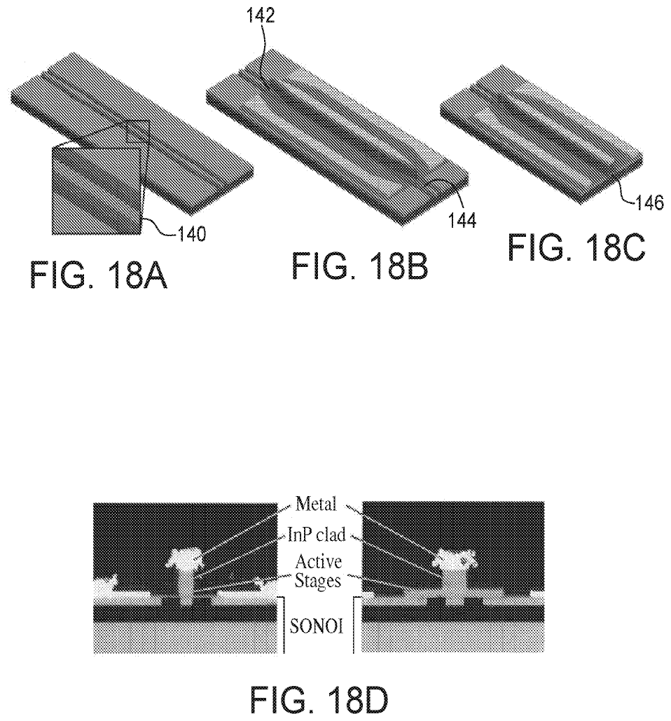

QCLs on foreign substrates have also been fabricated with a distributed feedback grating. Other feedback is also possible, including other gratings or loop mirrors. FIG. 18A shows a three-dimensional (3D) illustration of the SONOI waveguide with an etched DFB surface grating 140 underlying the III-V layers and FIG. 18B illustrates the DFB QCL, which consists of a hybrid Si/III-V active region coupled by III-V tapers 142 to passive silicon waveguides 144 on both sides. End facets are formed by mechanically polishing the passive SONOI waveguides. The 3-mm-long active region is positioned on top of a quarter-wavelength-shifted shallow DFB surface grating that extends throughout the underlying silicon waveguide. The SONOI waveguide is fully etched and 1.5 μm tall. FIG. 18C shows an integrated DFB QCL with one taper removed to expose a polished hybrid Si/III-V facet 146.

Before the silicon waveguide is etched, the grating is patterned onto the silicon with electron beam lithography (EBL) and formed with a C₄F₈/SF₆/Ar inductively coupled plasma (ICP) etch. The grating period employed for different devices on the chip ranges from 738 to 778 nm. Atomic force microscope (AFM) measurements of one device found a ˜31% etched silicon duty cycle and 28 nm etch depth.

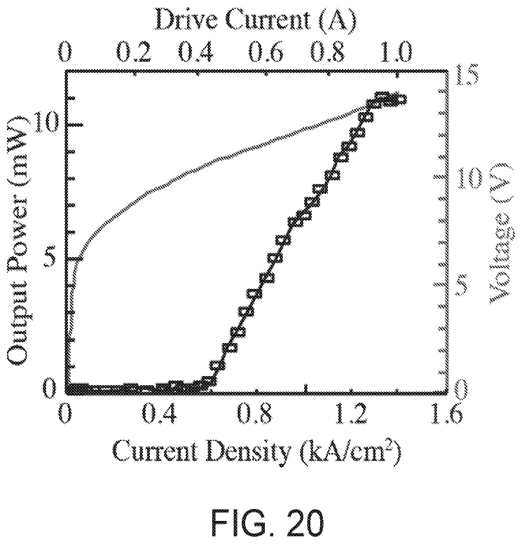

The silicon waveguides in the passive regions and output facets are 2 μm wide. However, the silicon waveguides expand underneath the III-V taper to aid the mode conversion. For subsequent measurements carried out to clarify the role of the tapers in the laser operation, the tapers adjacent to the output facet were removed by polishing back to immediately past the tapers. In that case, the silicon waveguide at the resulting hybrid Si/III-V output facet was slightly wider than within the rest of the hybrid active region. FIG. 20C depicts the laser structure with one taper removed. FIG. 18D shows an optical microscope image of hybrid Si/III-V output facets. The QCL included 30 stages. Flip chip bonding, rather than epitaxially growing the QCL on the foreign substrate, was used to integrate the QCL on the Si substrate. A thin bottom InP contact layer and thick top InP cladding were used to increase optical confinement in the silicon waveguide while preventing overlap with the top metal. The bonding can be achieved via a process that begins with forming vertical outgassing channels (VOCs) that are etched through the top silicon device layer on the SOI or SONOI substrate. A plasma activation is applied to the surface of both the silicon and III-V materials. The surfaces are bonded together, placed in a graphite fixture where pressure is applied, and annealed, e.g., at 300° C. for about 1 hour. The substrate of the III-V material is then removed. The pressure and the recipe for plasma activation will vary depending upon materials, as will anneal time and temperature.

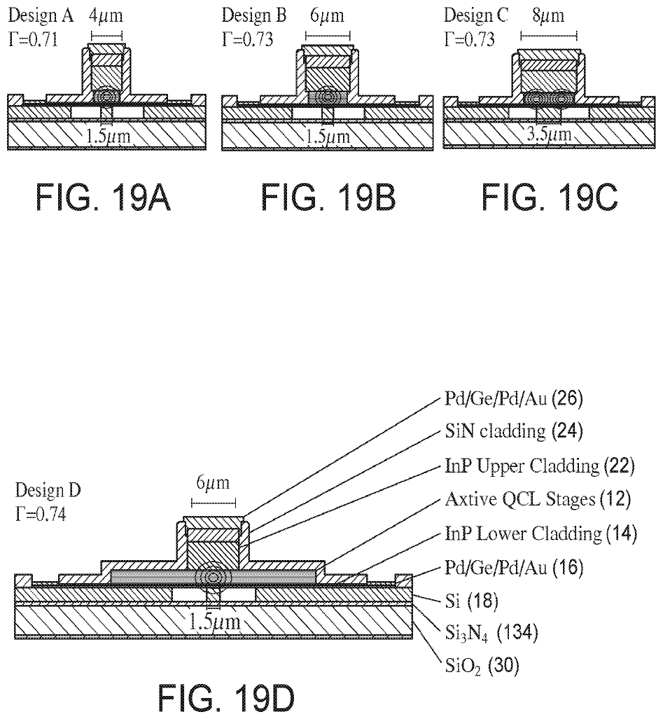

Four laser configurations with different active region waveguide geometries were tested. FIGS. 19A-191D shows active region cross-sections for the four designs labeled A-D. Designs A-C contain fully etched narrow III-V ridges, with mesa widths of 4 μm, 6 μm and 8 μm, respectively. Design D alternatively has a 6-μm-wide upper cladding combined with a 24-μm-wide active region. The width of the silicon waveguide underneath the active region is 1.5 μm for Designs A, B, and D and 3.5 μm for Design C. FIGS. 19A-19D also overlay simulated optical modes onto the four waveguide cross-sections, along with estimated transverse optical confinement factors (F) in the active QCL stages. Both the active region confinement and optical overlap with the gratings etched into the underlying silicon depend on the widths of the III-V and silicon waveguides 18. Single-mode operation requires careful design of the laser geometry, to optimize both the net modal gain and the guided-mode mirror reflectivity. The heterogeneous silicon platform provides enhanced engineering versatility that allows such optimization. For example, Design D, with its narrow silicon waveguide and wide active region, reduces the optical loss induced by sidewall roughness, while potentially maintaining operation in a single lateral mode. Since the current spreading below the lasing threshold is significant in QCLs, this is achieved at the expense of increasing the threshold current by the ratio of the active region width to the lateral modal extent. The far-field profiles appear to show that, in agreement with the mode simulations illustrated in FIGS. 19A-19D. Designs A, B, and D lase primarily in the TM₀₀ mode while Design C lases primarily in the higher-order TM₁₀ mode.

The DFB QCLs were tested. For testing, the DFB QCLs were driven with 250-ns-wide pulses at a 1 kHz repetition rate. The L-I-V characteristics at 20° C. of each device were measured both before and after removal of the III-V tapers. FIG. 20 shows pulsed output power and voltage vs. injection current density and current at 20° C. of an integrated DFB QCL of Design D with III-V tapers on both sides. Light is collected from the polished passive SONOI facet. FIG. 20 shows the best of the results for a device (of Design D) before the taper was removed (with the assumption that the current spreads uniformly over the 24-μm-wide active region). Although the threshold current density appears quite low (0.58 kA/cm²), the maximum output power is only 11 mW, and the differential slope efficiency is only 23 mW/A. These observations would be inconsistent if obtained for a conventional QCL geometry with cleaved facets, since the observed low efficiency implies a high loss, which should greatly increase the threshold current density. Other devices of all four designs also displayed relatively low threshold current densities of 0.6-1.2 kA/cm², but even lower maximum output powers of 1.2-4.1 mW. Several of the devices (of Designs B and C) did not produce enough light to measure.

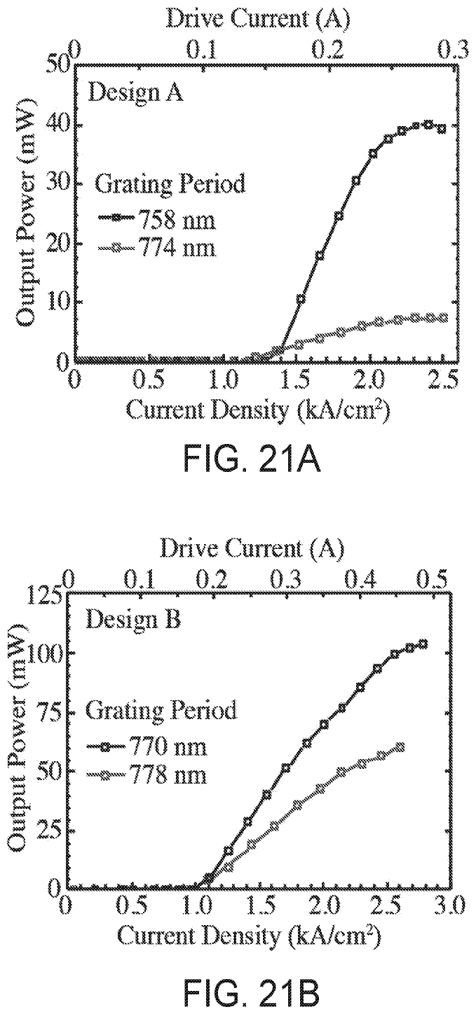

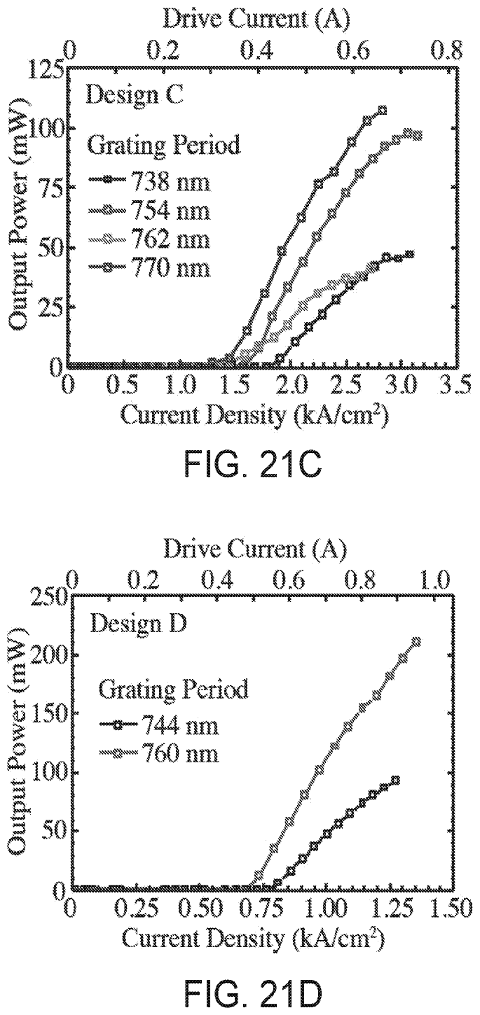

All of the lasers were re-measured following removal of the tapers from the output sides. FIG. 21A-21D plots the light intensity vs. injection current density for the lasers studied (two with Design A, two with Design B, four with Design C, and two with Design D). Specifically, pulsed output power vs. injection current density at 20° C. for DFB QCLs with the four different designs and various grating pitches. Light is collected from a polished hybrid Si/III-V facet. In all cases, the threshold current densities increased only slightly (by 7%-26%) while the differential efficiencies improved dramatically (by factors of 14-51). Furthermore, the devices that emitted too little light to measure when both tapers were intact became fully operational, with performance comparable to the others. Apart from one anomalous device (Design A), the slope efficiencies following removal of the tapers ranged from 161 mW/A (for a laser with Design C) to 541 mW/A (Design D). The maximum measured output power was 211 mW (not yet saturated), as seen in FIG. 21D. The threshold current densities ranged from 0.71 to 1.36 kA/cm² for Designs A, B, and D, while the thresholds for devices with Design C were somewhat higher (1.44-1.83 kA/cm²).

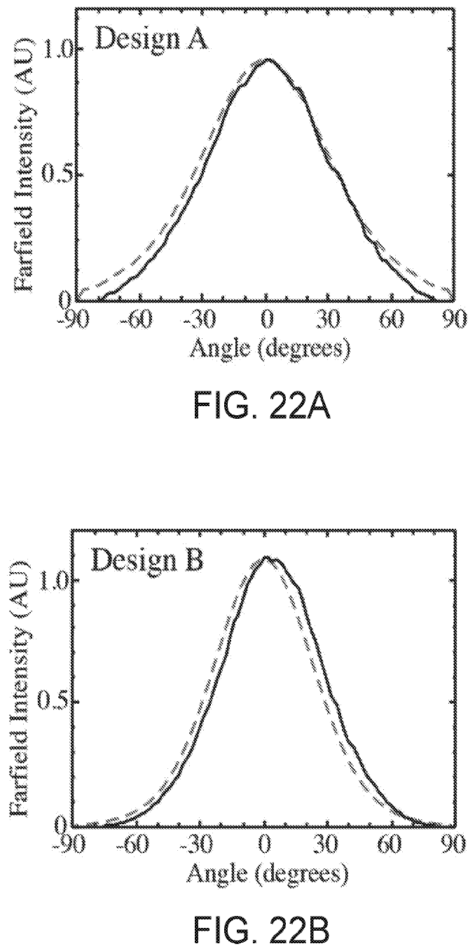

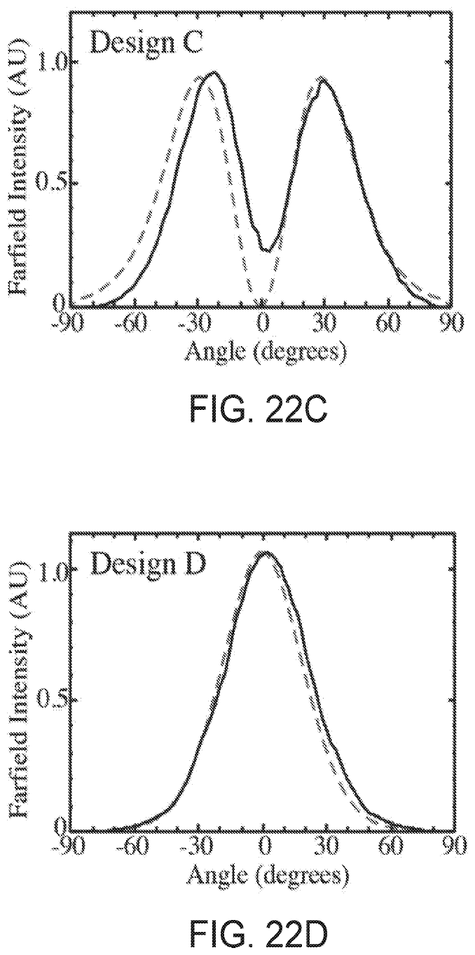

FIGS. 22A-22D show slow-axis far field profiles for one laser of each active region design, at currents of 200, 350, 500, and 700 mA for Designs A-D, respectively. The solid curves show the measure profiles, while the dashed curves show the simulated profiles for the TM₀₀ mode in FIGS. 22A, 22B, and 22D and the TM₁₀ mode in FIG. 22C. The solid lines represent the slow-axis far-field profiles for one laser with each waveguide geometry. The single-lobe distributions observed for devices with Designs A, B, and D indicate lasing primarily in the fundamental TM₀₀ mode. The two lobes seen in the profile for Design C indicate that the higher-order TM₁₀ mode dominates the emission, although the absence of a complete central null suggests that the fundamental mode also contributes. The dashed curves are FIMMWAVE simulations of the far-field distributions corresponding to the TM₀₀ and TM₁₀ modes of each waveguide design at the hybrid Si/III-V facets. These agree well with the measured profiles, except for Design C near zero degrees. The fast-axis profile measured for the device with Design B displays a similar symmetric single-lobe distribution.

These mode selections are generally consistent with the optical confinement distributions simulated for each of the active cross-section designs. The second-order TM₁₀ mode is calculated to be above cutoff for the narrow 4 μm mesa of Design A. While Design B supports a TM₁₀ mode with high active region confinement, that mode resides almost entirely in the III-V mesa, overlaps significantly less with the Si surface grating, and interacts more with the mesa sidewalls. The 3.5-μm-wide Si waveguide of Design C is wide enough to contain much of the TM₀₀ mode, which limits its active region confinement (Γ=0.46) compared to the TM₁₀ mode (Γ=0.73). However, this configuration may allow both modes to lase simultaneously, given that the fundamental mode may suffer less from sidewall scattering loss. The apparent operation of the laser with Design D in a single mode is not as easily explained, since both the TM₀₀ and TM₁₀ modes have sufficient overlap with the active region and grating. One possibility is that the wider higher-order mode may have additional loss associated with optical leakage into the silicon slab on both sides of the 4-μm-wide air trenches that define the silicon waveguide.

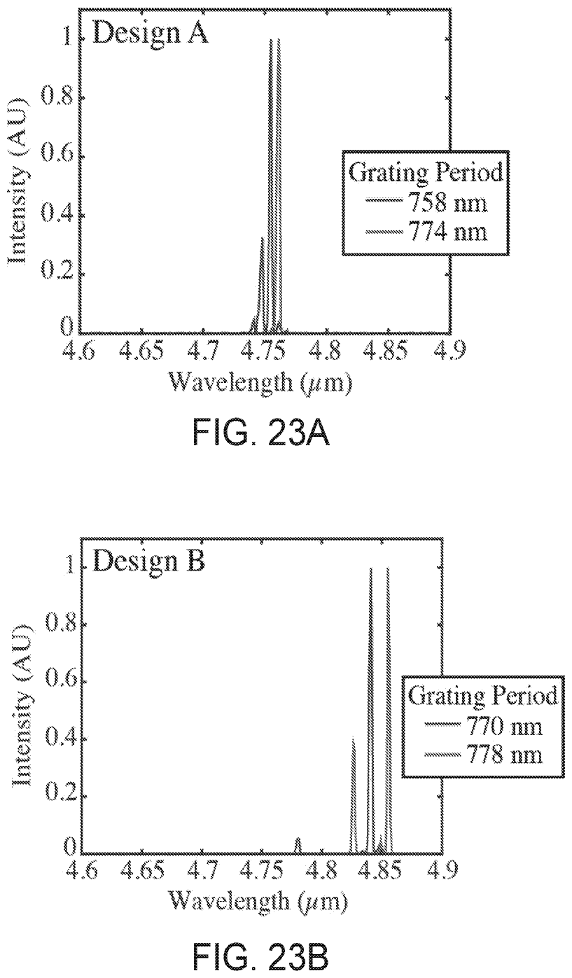

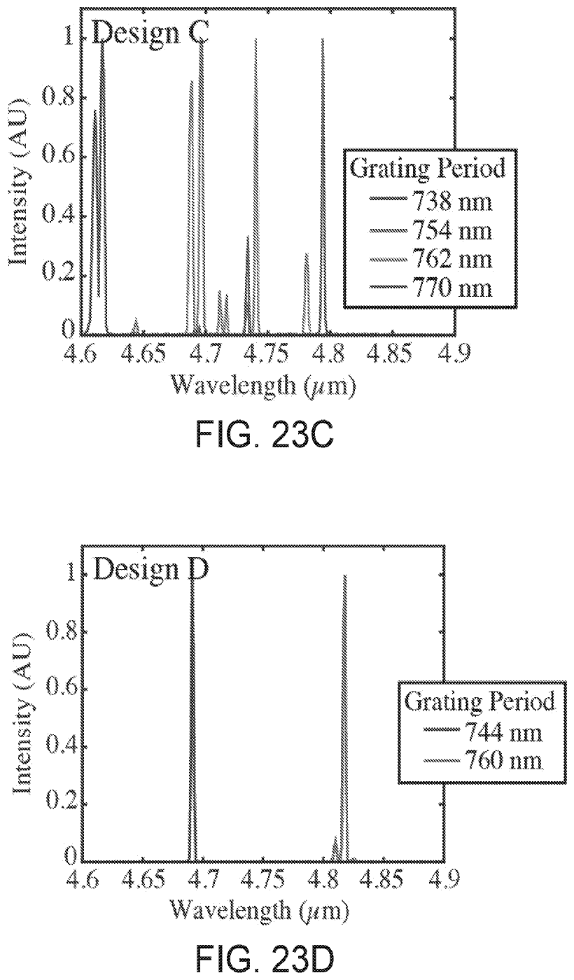

FIGS. 23A-23D show normalized emission spectra at 20° C. of DFBs with the four designs, as measured with a monochromator. The spectra were obtained at currents of ≈0.3 A for Designs A and B, 0.5 A for Design C, and 0.7 A for Design D. The legends show the DFB grating pitches of each device. Spectral measurements at 20° C. were acquired with a Digikrom 0.5 m monochromator with 1.5 nm resolution. In all cases, a primary lasing peak at a wavelength ranging from 4.62 to 4.86 μm tracks the central Bragg frequency of the particular DFB grating, although many of the lasers emit in multiple modes. The weaker spectral features likely result from Fabry-Perot resonances corresponding to reflections between the polished hybrid Si/III-V facet and the remaining III-V taper. Inconsistencies of these modes from device to device may be attributed to variations in the taper fabrication associated with non-uniform undercut at the taper tip across the chip after wet etching of the active region.

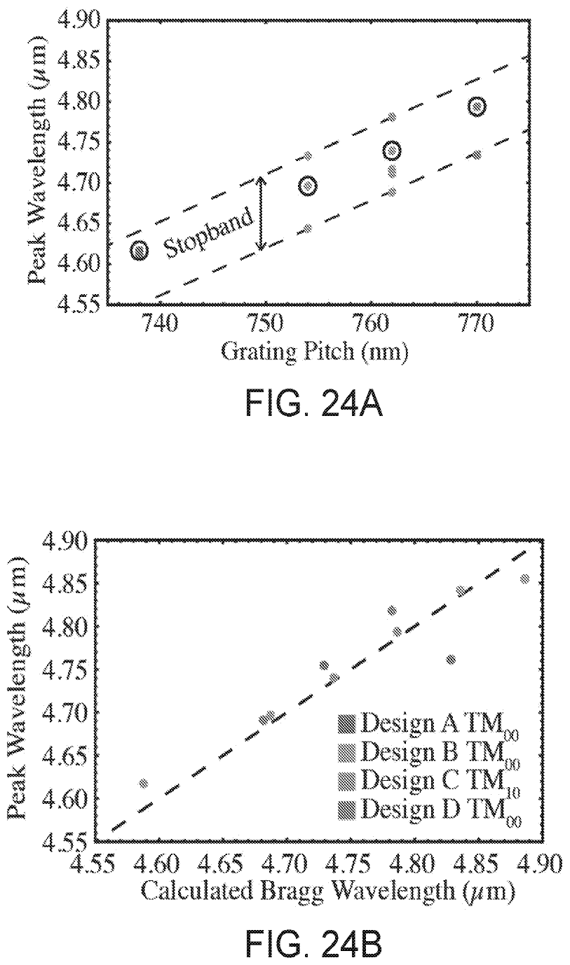

FIGS. 24A-24B show measured peak wavelengths as a function of DFB grating pitch for all four lasers of Design C, from the spectral data of FIG. 23C. Multiple points of the same color (a single grating pitch) represent the multiple spectral peaks for that device. The circled points represent the strongest peak for that device. The dashed lines show that modes lasing at the edges of the 90-nm-wide stopband track the fabricated grating pitch. FIG. 24B shows measured peak wavelength as a function of calculated Bragg wavelength for the strongest lasing mode of the devices shown in FIGS. 23A-23D.

For the lasers with Designs A and D, the central mode of the λ/4-shifted DFB grating appears split by the additional cavity resonance, while the lasers with Designs B and C show evidence for higher-order grating modes at the edges of the stop-band. For all four lasers with Design C, FIG. 24A plots the wavelengths of the strongest peaks as a function of grating periodicity. The central peak (circled points) and two side modes follow a linear trend with the grating period, indicated by the dashed lines. This suggests a grating stopband width of 90 nm for this design.

FIG. 24B shows the wavelength of the strongest peak for each laser with all four designs vs. the estimated Bragg wavelength of the DFB grating. The first-order Bragg wavelength is calculated from the coupled mode theory approximation, λ_{B}=2 n̅_{eff}Λ, where A is the pitch of the grating and n̅_{eff} is the average effective index of the mode. The average effective index is approximated by an average of the effective indices of the optical mode simulated in FIMMWAVE (TM₀₀ for Designs A, B, and D, and TM₁₀ for Design C) with and without the 28 nm grating air gap, weighted by the measured duty cycle of the grating. The Bragg wavelength calculated directly from this value of n̅_{eff} is, on average, 1% lower than the measured peak wavelength. This inconsistency is most likely attributable to an overestimation of the effective index by the mode solver. Accordingly, the n̅_{eff} values used to calculate the Bragg Wavelength for FIG. 7b are adjusted by a factor of 0.99. Note the nearly linear dependence of the experimental peak emission wavelength on the calculated Bragg wavelength. The only significant departure is for the same laser with Design A (emitting at ≈4.76 μm) that displayed anomalously low slope efficiency.

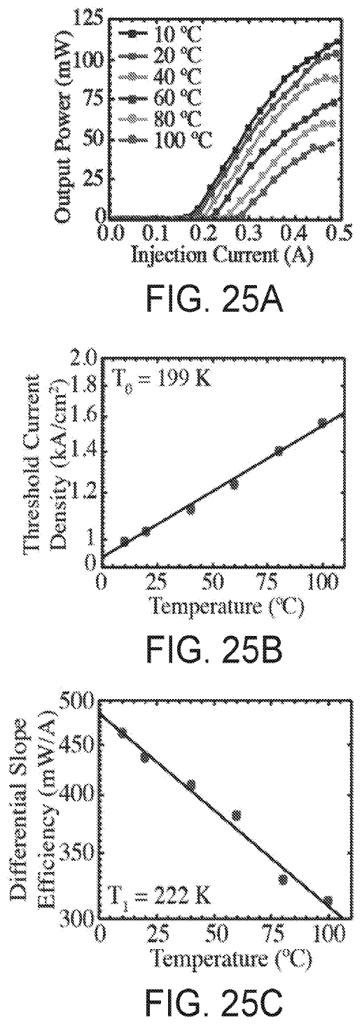

FIGS. 25A-25C show pulsed output power for a laser of Design B at temperatures ranging from 10° C. to 100° C.; Corresponding threshold current density vs. temperature, which yields a characteristic temperature of T₀=199 K; and Corresponding differential efficiency vs. temperature, which yields a characteristic temperature of T₁=222 K.

In particular, FIG. 25A shows the light output vs. injection current for the laser of Design B with a grating period of 770 nm, measured at a range of temperatures from 10 to 100° C. The threshold current density and differential slope efficiency vs. temperature are shown in FIGS. 25B and 25C, respectively. The characteristic temperatures of T₀=199 K for threshold and T₁=222 K for efficiency are extracted from the exponential fits indicated by the lines.

Both relatively high pulsed characteristic temperatures are much higher than those observed for the Fabry-Perot QCLs on silicon, which lased in pulsed mode only to 60° C. One possibility is that the gain peak is better matched to the Bragg wavelength at higher temperatures. The much higher T₀ and T₁ values are consistent with both the significantly lower room temperature threshold current density compared to the Fabry-Perot devices and the relatively low injector sheet-doping density (˜0.5×10¹¹ cm⁻²).

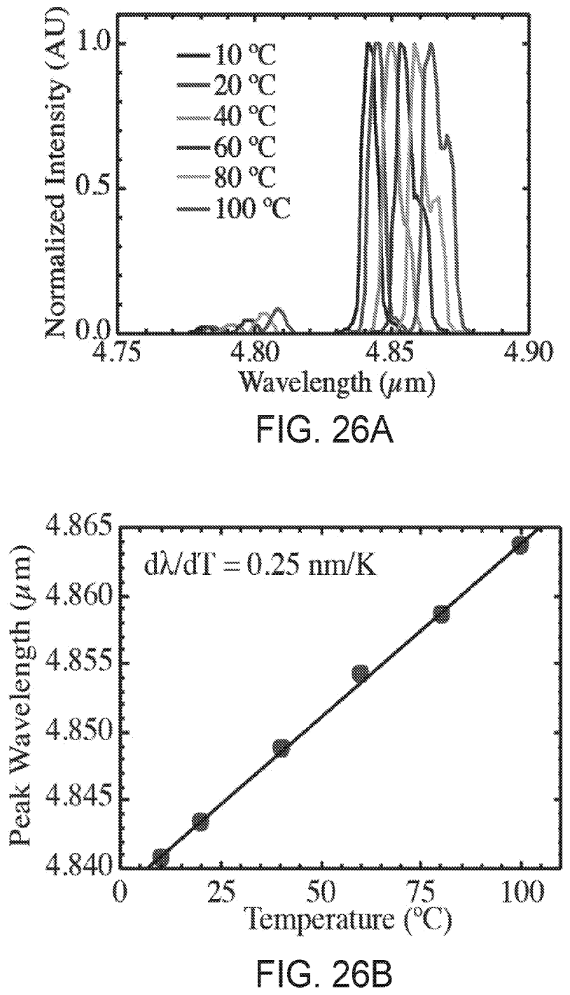

FIGS. 26A and 26B show temperature-dependent emission spectra for the same laser of Design B whose temperature-dependent L-I characteristics are shown in FIG. 25; and Peak wavelength as a function of temperature. FIG. 26A shows the emission spectra for the same device over the same range of temperatures. FIG. 26B shows the primary lasing peak wavelength as a function of temperature. The single primary peak tunes at a rate of 0.25 nm/K, which is consistent with the expected shift of the modal index that governs the DFB mode rather than the shift of the gain peak. The low threshold current densities and high characteristic temperatures, indicate that CW operation of these lasers at room temperature with improved heat dissipation can be achieved.

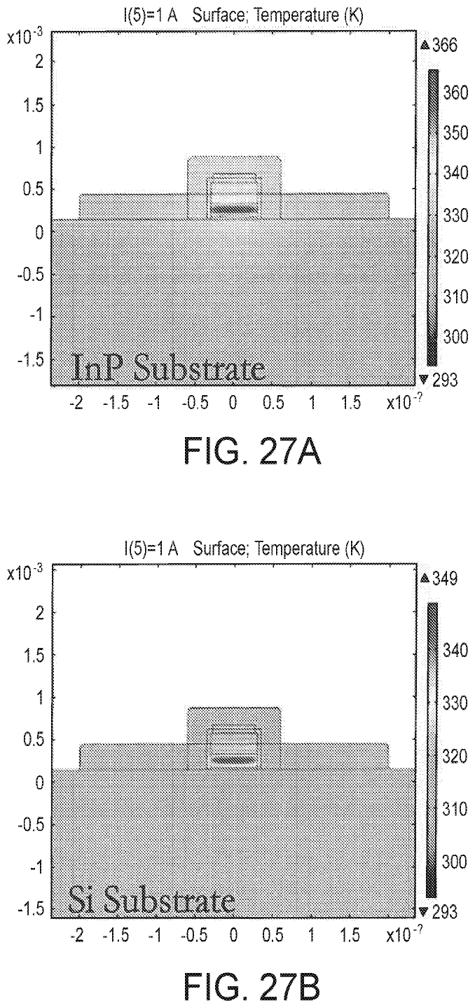

The active device portions of experimental structures that were integrated via wafer bonding, can also be formed via epitaxial growth discussed with respect to FIGS. 3A-4B. Both epitaxial growth of QCLs on silicon and integration by bonding QCLs on silicon yield thermal advantages. FIGS. 27A and 27B compare a 2-dimensional COMSOL simulation of the heat profile in a 6 μm-wide quantum cascade laser ridge on a native lattice matched InP substrate to a laser of the invention on a silicon substrate. The simulations assume an ideal case where power is dissipated only from the voltage drop of the radiative transitions in the active region, and neglects finite series or contact resistance in real devices, which will add additional heating to the overall device. The simulated active region is 1.5 μm-thick and is representative of 30 QCL active stages for 4.8 μm emission. A bias voltage of 7.75 V is applied for all injection currents. Practical operating voltages for devices at this wavelength are usually above around 10 volts and can be much higher depending on the design and operating current. The active region and InP thermal conductivity values were from Liu et al, “A mini-staged multi-stacked quantum cascade laser for improved optical and thermal performance,” Semicond. Sci. Technol. 24, 075023 (2009). The heat capacity and density of the active region and InP shown were from Chaparala et al., “Design Guidelines for Efficient Thermal Management of Mid-Infrared Quantum Cascade Lasers,” IEEE Transactions on Components, Packaging and Manufacturing Technology 1, 1975-1982 (2011). A maximum temperature improvement of ˜17 K is seen by using a Si substrate when the injection current (corresponding to the threshold current) is 1 A (˜7.75 Watts, corresponding to a heat contribution of ˜2.15×10¹⁴ W/m³). Different values of thermal conductivity and heat capacity, and different laser geometries and configurations will affect the maximum temperature improvement, but an improvement is expected in all cases where heat is primarily dissipated down through the substrate, and where that InP substrate is replaced with a silicon substrate. The InP substrate can be replaced by a silicon substrate through either epitaxial growth of the QCL on silicon rather than InP, or by bonding the QCL layers (which were grown on InP) onto a silicon substrate.

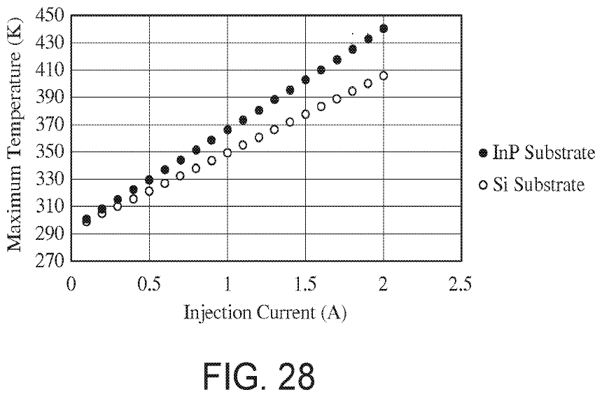

FIG. 28 plots the simulated maximum temperature in the structures as a function of injection current (or dissipated power), where further differentiation of maximum device temperature between the designs is seen for higher threshold injection currents (up to ˜34 K when injected with 2 A or 15.5 Watts). Because the simulations neglect the additional non-idealities present in a real device, the simulations represent a conservative estimate of the heat sinking improvement when switching to growth on silicon substrates.

FIG. 28 estimates the maximum temperature when the injected current is injected below lasing threshold assuming all injected power is dissipated as heat. In a real device operating above threshold, some of the injected power contributes to light emission rather than heat. However, even above threshold, typically 70-80% of the current injected into a QCL will turn into heat.

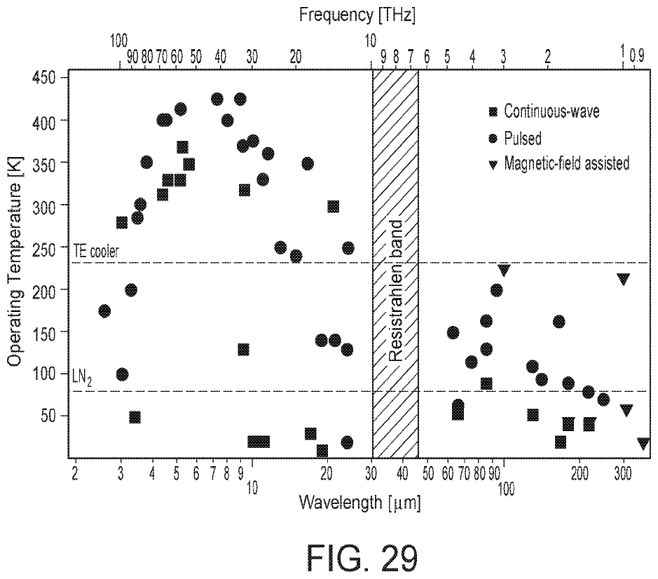

FIG. 29 shows a plot of maximum operating temperature versus emission wavelength for quantum cascade lasers. Typical material systems for high performance QCLs are InGaAs/lnAIAs or InGaAs/AIAsSb lattice matched to InP with corresponding wavelengths of ˜3-25 μms. GaAs-based QCLs such as those utilizing the GaAs/AIGaAs system are preferable for longer mid-infrared (>8.5 μm) and Terahertz emission. Quantum cascade lasers constructed from the alternative InAs/AlSb material system lattice matched to InAs or GaSb substrates can potentially emit wavelengths as short as 1.9 μm [See, A Krier, “Mid-Infrared Semiconductor Optoelectronics, Springer Series in Optical Sciences,” (Springer London, 2006), Vol. 118]. Lasing has been demonstrated with these materials at wavelengths as short as 2.6 μm which is the shortest wavelength QCL reported to date, to our knowledge [See, Cathabard et al., “Quantum cascade lasers emitting near 2.6 μm,” Appl. Phys. Lett. 96, 141110 (2010)]. However, shorter wavelengths such as the important telecom/datacom wavelengths of 1.3 and 1.55 μm are possible to obtain using specific material systems such as the Nitrides (such as InAlN/GaN), which offer a much higher conduction band offset than typical Arsenides and Phosphides and correspondingly larger intersubband transition energies [See, Hefstetter et al., “Intersubband Transition-Based Processes and Devices in AlN/GaN-Based Heterostructures,” Proc. IEEE 98, 1234-1248 (2010).].

FIG. 29 reveals that the maximum operating temperature of these devices, especially in continuous wave operation, is fairly limited. Room temperature continuous wave operation has not been achieved for devices emitting beyond 20 μm.

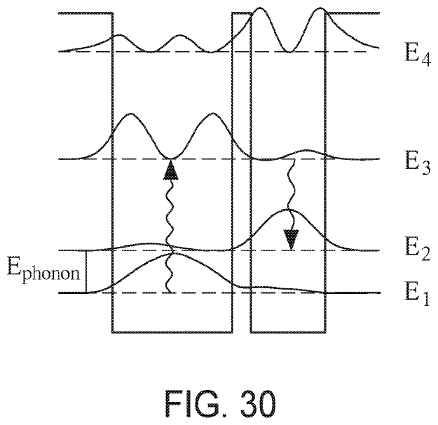

Some failures have been observed by the inventors in which most of the substrate and epi layers have melted and re-crystallized into polycrystalline material due to excessive heating in the device. Semiconductor laser reliability (defined as mean time to failure-MTTF). The present unipolar light devices integrated with silicon are expected to provide improvements to the maximum operating temperature, radiative efficiency, and reliability, depending on the geometry and thermal dissipation designs employed. The dissipation of heat will avoid such problems, while the inventors have also recognized that defects at the interface will not have a significant effect on performance of the QCL or other unipolar light emitter. FIG. 30 shows the band diagram of an example unipolar device having coupled quantum wells. See, O. Gauthier-Lafaye, P. Boucaud, F. H. Julien, S. Sauvage, S. Cabaret, J. M. Lourtioz, V. Thierry-Mieg, and R. Planel, “Long-wavelength (≈15.5 μm) unipolar semiconductor laser in GaAs quantum wells,” Appl. Phys. Lett. 71, 3619-3621 (1997). This device can be either heterogeneously integrated by bonding with a foreign substrate or epitaxially grown on a foreign substrate in accordance with the invention.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A light emitting device comprising a unipolar light emitter structured from materials arranged to provide light emission via intersubband transitions of a single type of carrier in either of the conduction band or valence band integrated with a foreign surface.

2. The device of claim 1, wherein the materials comprise Group III-V device layers of (InₓAl_{y}Ga_{z})_{0.5}(AsᵤPᵥN_{w})_{0.5}, where x+y+z=1, u+v+w=1.

3. The device of claim 1, wherein the materials comprise Group III-V device layers, some of which contain Sb, of (InₓAl_{y}Ga_{z})_{0.5}(SbₜAsᵤPᵥN_{w})_{0.5}, where x+y+z=1, t+u+v+w=1.

4. The device of claim 1, wherein the materials of the unipolar emitter comprise Group II-VI device layers including Zn, Cd, or Hg with O, S, Se, or Te.

5. The device of claim 1, wherein the materials of the unipolar emitter comprise Group IV device layers including Ge, Si, or Sn.

6. The device of claim 1, wherein the unipolar light emitter comprises a quantum cascade laser.

7. The device of claim 1, wherein the unipolar light emitter includes quantum dots or quantum dashes, rather than quantum wells, for light emission.

8. The device of claim 1, wherein the unipolar light emitter comprises a quantum dot cascade laser.

9. The device of claim 1, wherein the unipolar light emitter emits light of a wavelength in selected from the group consisting of the wavelength 1 μm to 1 m, the mid-infrared wavelength range 2-20 μm, the Terahertz regime, 20 μm to 1 mm, a wavelength near 1.55 μm, and a wavelength near 1.3 μm.

10-14. (canceled)

15. The device of claim 1, wherein the active layers of the unipolar light emitter are wafer bonded to the foreign surface.

16. The device of claim 1, wherein the active layers of the unipolar light emitter are epitaxially grown on the foreign surface.

17. The device of claim 16, comprising a cladding layer on the foreign surface.

18. The device of claim 1, wherein the materials are selected and arranged such that radiative relaxations dominate over non-radiative relaxations.

19. The device of claim 1, wherein the foreign surface comprises one of the group consisting of silicon, germanium, glass, sapphire, diamond, an oxide layer, a buffer layer, a waveguide on a substrate.

20-26. (canceled)

27. The device of claim 1, wherein the foreign surface comprises silicon and wherein the unipolar light emitter comprises a quantum cascade laser heterogeneously integrated on the silicon with a silicon-on-nitride-on-insulator (SONOI) ultra-broadband waveguide platform.

28-29. (canceled)

30. The device of claim 19, wherein the foreign surface is a waveguide on a substrate, and further comprising a buffer layer, bottom metal, active stages, cladding above and below the active stages, and a top metal.

31-32. (canceled)

33. The device of claim 30, wherein the substrate comprises silicon and the waveguide comprises germanium.

34. The device of claim 30, wherein the substrate comprises silicon and the waveguide comprises silicon with buried oxide separating the silicon waveguide from the silicon substrate.

35. The device of claim 30, wherein the substrate comprises silicon and the waveguide comprises silicon with buried oxide and silicon nitride separating the silicon waveguide from the silicon substrate.

36. The device of claim 30, wherein the substrate comprises silicon and the waveguide comprises silicon with silicon nitride separating the silicon waveguide from the silicon substrate.

37. The device of claim 30, wherein the substrate comprises silicon and the waveguide comprises silicon nitride with silicon dioxide separating the silicon nitride waveguide from the silicon substrate.

38. The device of claim 1, comprising a substrate, bottom metal, active stages, cladding above and below the active stages, cladding around the active regions and a top metal.

39. The device of claim 38, wherein the cladding above and below consists of InP, and the cladding around consists of SiN.

40. The device of claim 38 wherein the unipolar light emitting device is part of a photonic integrated circuit, is integrated with passive waveguide regions comprised of III-V materials, is integrated with passive waveguide regions comprised of the same material which comprises the unipolar light emitter, is integrated with passive waveguide regions comprised of chalcogenide glasses or is integrated with passive or active waveguides or devices comprised of materials integrated after the unipolar light emitting device is integrated with the foreign surface.

41-44. (canceled)
